(19) United States
(12) Patent Application Publication
(10) Pub. No.: US 2025/0185468 A1
(43) Pub. Date: Jun. 5, 2025

(54) DISPLAY PANEL AND MANUFACTURING METHOD FOR THE SAME

(71) Applicant: Samsung Display Co., Ltd., Yongin-si (KR)

(72) Inventors: HYUNEOK SHIN, Yongin-si (KR); JOONYONG PARK, Yongin-si (KR); SUKYOUNG YANG, Yongin-si (KR); DONGMIN LEE, Yongin-si (KR)

(73) Assignee: Samsung Display Co., Ltd., Yongin-si (KR)

(21) Appl. No.: 18/899,497

(22) Filed: Sep. 27, 2024

(30) Foreign Application Priority Data
Dec. 4, 2023 (KR) 10-2023-0173480

(51) Int. Cl. H10K 59/122; H10K 59/12

(52) U.S. Cl. CPC H10K 59/122; H10K 59/1201

(57) ABSTRACT

Provided is a display panel including a base layer, a pixel-defining film disposed on the base layer and having a light-emitting opening, a partition wall disposed on the pixel-defining film and having a partition wall opening overlapping the light-emitting opening and a groove overlapping the pixel-defining film, and a light-emitting element having an anode, a light-emitting pattern, and a cathode in contact with the partition wall, and disposed in the light-emitting opening and the partition wall opening.

### CROSS-REFERENCE TO RELATED APPLICATIONS

This U.S. non-provisional patent application claims priority to and benefits of Korean Patent Application No. 10-2023-0173480 under 35 U.S.C. § 119, filed on Dec. 4, 2023, in the Korean Intellectual Property Office (KIPO), the entire contents of which are incorporated herein by reference.

### BACKGROUND

The disclosure herein relates to a display panel and a manufacturing method for the same, and more particularly, to a display panel with improved display quality.

A display device that provides an image to a user, such as a television, a monitor, a smartphone, and a tablet computer, includes a display panel for displaying the image. Various display panels are being developed such as a liquid crystal display panel, an organic light-emitting display panel, an electro-wetting display panel, and an electrophoretic display panel.

The organic light-emitting display panel may include an anode, a cathode, and a light-emitting pattern. The light-emitting pattern may be separated for each light-emitting region, and the cathode may provide a common voltage to the light-emitting regions.

### SUMMARY

The disclosure provides a display panel in which a light-emitting element is formed without using a metal mask and which has improved display quality, and a manufacturing method for the display panel.

The technical objectives to be achieved by the disclosure are not limited to those described herein, and other technical objectives that are not mentioned herein would be clearly understood by a person skilled in the art from the description of the disclosure.

An embodiment of the disclosure provides a display panel including a base layer, a pixel-defining film disposed on the base layer and having a light-emitting opening, a partition wall disposed on the pixel-defining film, and having a partition wall opening overlapping the light-emitting opening and a groove overlapping the pixel-defining film, and a light-emitting element including an anode, a light-emitting pattern, and a cathode in contact with the partition wall, and disposed in the light-emitting opening and the partition wall opening.

In an embodiment, the groove may be concave from an upper surface of the partition wall in a thickness direction of the base layer.

In an embodiment, the partition wall may include first portions disposed on the pixel-defining film, second portions extending from the first portions in a thickness direction of the base layer, and third portions extending from the second portions toward the center of the partition wall opening.

In an embodiment, the third portions protruding from the second portions may include tip portions.

In an embodiment, the partition wall opening may include a first region defined by the third portions of the partition wall and a second region defined by the second portions of the partition wall, and a width of the first region in a direction may be smaller than a width of the second region in the direction.

In an embodiment, a length of the partition wall from lower surfaces of the first portions, adjacent to the second portions, to lower surfaces of the third portions may be in a range of about 0.5 μm to about 1 μm.

In an embodiment, the display panel may further include a lower inorganic encapsulation pattern which covers the light-emitting element, and the lower inorganic encapsulation pattern may fill the partition wall opening.

In an embodiment, the display panel may further include an organic encapsulation film disposed on the lower inorganic encapsulation pattern, and the organic encapsulation film may fill the groove.

In an embodiment, the partition wall may include at least one of molybdenum (Mo), tungsten (W), and a molybdenum-tungsten (Mo—W) alloy.

In an embodiment, the partition wall may include a first partition wall layer disposed on the pixel-defining film and a second partition wall layer disposed on the first partition wall layer.

In an embodiment, the first partition wall layer may include at least one of molybdenum (Mo), tungsten (W), and a molybdenum-tungsten (Mo—W) alloy.

In an embodiment, the second partition wall layer may include at least one of titanium (Ti) and aluminum (Al).

In an embodiment, the partition wall may have a thickness in a range of about 0.2 μm to about 0.5 μm.

In an embodiment of the disclosure, a manufacturing method for a display panel includes providing a preliminary display panel including a base layer, an anode disposed on the base layer, and a pixel-defining film covering the anode, forming, on the preliminary display panel, an auxiliary layer overlapping the anode, forming a preliminary partition wall on the pixel-defining film and the auxiliary layer, etching the preliminary partition wall and the auxiliary layer to form a partition wall including partition wall opening, etching the pixel-defining film to form a light-emitting opening overlapping the partition wall opening, and forming a light-emitting element in the light-emitting opening and the partition wall opening.

In an embodiment, the etching of the preliminary partition wall and the auxiliary layer to form the partition wall including the partition wall opening may include etching the preliminary partition wall to form a first region of the partition wall opening, and etching the auxiliary layer to form a second region of the partition wall opening.

In an embodiment, the partition wall may include a groove overlapping the pixel-defining film, and the groove may be concave from an upper surface of the partition wall in a thickness direction of the base layer.

In an embodiment, the manufacturing method may further include forming a lower inorganic encapsulation pattern which covers the light-emitting element, and the lower inorganic encapsulation pattern may fill the partition wall opening.

In an embodiment, the manufacturing method may further include forming an organic encapsulation film on the lower inorganic encapsulation pattern, and the organic encapsulation film may fill the groove.

In an embodiment, the forming of the preliminary partition wall on the pixel-defining film and the auxiliary layer may include depositing at least one of molybdenum (Mo), tungsten (W), and a molybdenum-tungsten (Mo—W) alloy.

In an embodiment, the forming of the preliminary partition wall on the pixel-defining film and the auxiliary layer may include depositing a first preliminary partition wall layer on the pixel-defining film and the auxiliary layer, and depositing a second preliminary partition wall layer on the first preliminary partition wall layer.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a schematic perspective view of a display device according to an embodiment of the disclosure;

FIG. 1B is a schematic exploded perspective view of a display device according to an embodiment of the disclosure;

FIG. 2 is a schematic cross-sectional view of a display module according to an embodiment of the disclosure;

FIG. 3 is a schematic plan view of a display panel according to an embodiment of the disclosure;

FIG. 4 is a schematic enlarged plan view illustrating a portion of a display region of a display panel according to an embodiment of the disclosure;

FIG. 5 is a schematic cross-sectional view taken along line I-I′ of FIG. 3;

FIG. 6 is a schematic cross-sectional view taken along line II-II′ of FIG. 4;

FIGS. 7A to 7L are schematic cross-sectional views illustrating some steps of a manufacturing method for a display panel according to an embodiment of the disclosure;

FIG. 8 is a schematic cross-sectional view taken along line I-I′ of FIG. 3; and

FIG. 9 is a schematic cross-sectional view taken along line I-I′ of FIG. 3.

### DETAILED DESCRIPTION OF THE EMBODIMENTS

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Like reference numerals or symbols refer to like elements throughout. In the drawings, the thickness, the ratio, and the size of the element may be exaggerated for effective description of the technical contents.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the disclosure. Similarly, a second element, component, region, layer or section may be termed a first element, component, region, layer or section. As used herein, the singular forms, such as “a,” and “an,” are intended to include the plural forms as well, unless the context clearly indicates otherwise.

Also, terms of “below,” “on lower side,” “above,” “on upper side,” or the like may be used to describe the relationships of the elements illustrated in the drawings. These terms have relative concepts and are described on the basis of the directions indicated in the drawings.

It will be further understood that the terms “includes” and/or “have,” when used in this specification, specify the presence of stated features, integers, steps, operations, elements, components, and/or groups thereof, but do not preclude the presence or addition of one or more other features, integers, steps, operations, elements, components, and/or groups thereof.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure are described with reference to the accompanying drawings.

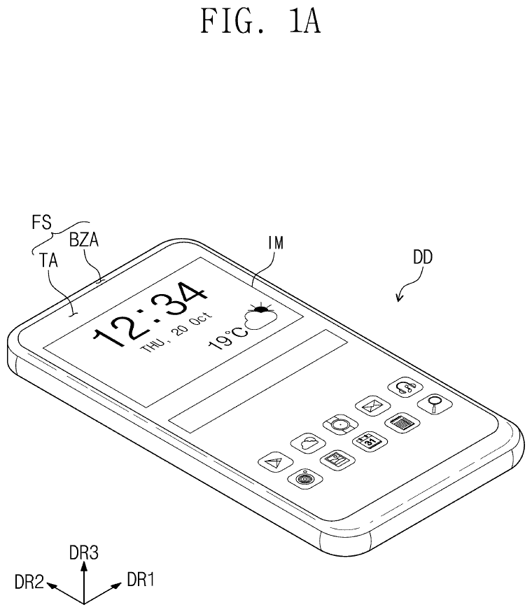

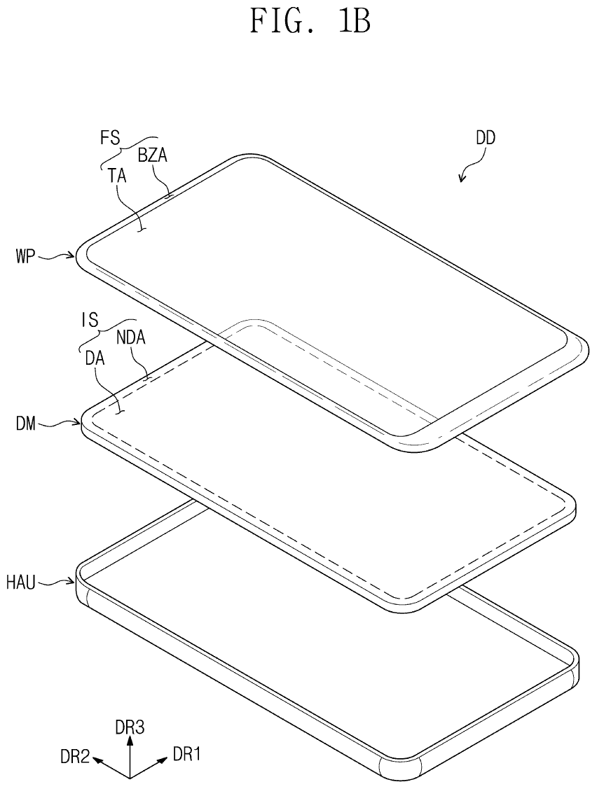

FIG. 1A is a schematic perspective view of a display device DD according to an embodiment of the disclosure, and FIG. 1B is a schematic exploded perspective view of the display device DD according to an embodiment of the disclosure.

In an embodiment, the display device DD may be a large electronic apparatus such as a television, a monitor, or a billboard. The display device DD may be a small- or medium-sized electronic apparatus such as a personal computer, a laptop computer, a personal digital assistant, a car navigation system, a game console, a smartphone, a tablet computer, and a camera. However, this is an example, and another display device may also be adopted unless it deviates from the idea of the disclosure. FIGS. 1A and 1B illustrate the display device DD as the smartphone.

Referring to FIGS. 1A and 1B, the display device DD may display an image IM on a display surface FS parallel to each of a first direction DR1 and a second direction DR2 in a third direction DR3. The image IM may include a still image and/or a dynamic image. FIG. 1A illustrates a clock and icons as an example of the image IM. The display surface FS on which the image IM is displayed may correspond to a front surface of the display device DD.

In this embodiment, a front surface (or upper surface) and a rear surface (or lower surface) of each of members are defined on the basis of a direction in which the image IM is displayed. The front surface and the rear surface may be opposite to each other in the third direction DR3, and the normal direction of each of the front surface and the rear surface may be parallel to the third direction DR3. Directions indicated by the first to third directions DR1, DR2, and DR3 may be relative concepts, and may thus be changed to other directions. In this specification, “on a plane” or “in a plan view” may refer to a state when an object is viewed in the third direction DR3.

The display device DD may include a window WP, a display module DM, and/or a housing HAU. The window WP may be coupled to the housing HAU to form the exterior of the display device DD.

The window WP may include an optically transparent insulating material. For example, the window WP may include glass or plastic. A front surface of the window WP may define the display surface FS of the display device DD. The display surface FS may include a transmission region TA and a bezel region BZA. The transmission region TA may be an optically transparent region. For example, the transmission region TA may have a visible light transmittance of about 90% or more.

The bezel region BZA may be a region having relatively lower light transmittance than that of the transmission region TA. The bezel region BZA may define the shape of the transmission region TA. The bezel region BZA may be adjacent to the transmission region TA, and may surround the transmission region TA. However, this is illustrated as an example, and in an embodiment, the bezel region BZA of the window WP may be omitted. The window WP may include at least one functional layer of an anti-fingerprint layer, a hard-coating layer, or an anti-reflection layer, and is not limited to any one embodiment of the disclosure.

The display module DM may be disposed under the window WP. The display module DM may be a component that substantially generates the image IM. The image IM generated by the display module DM may be displayed on a display surface IS of the display module DM, and may be viewed by a user through the transmission region TA.

The display module DM may include a display region DA and a non-display region NDA. The display region DA may be activated in response to electrical signals. The non-display region NDA may be adjacent to the display region DA. The non-display region NDA may surround the display region DA. The non-display region NDA may be covered by the bezel region BZA, and may thus be invisible from the outside.

The housing HAU may be coupled to the window WP. The housing HAU may be coupled to the window WP to provide an inner space (e.g., a predetermined or selectable inner space). The display module DM may be accommodated in the inner space.

The housing HAU may include a material having relatively high rigidity. For example, the housing HAU may include frames and/or plates including glass, plastic, or metal, or composed of a combination thereof. The housing HAU may stably protect components of the display device DD, accommodated in the inner space, from external impact.

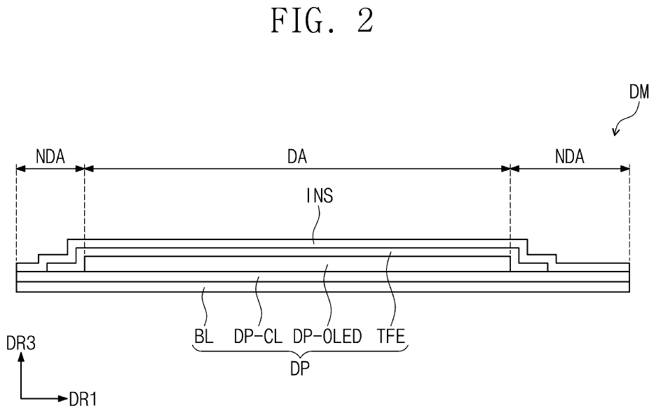

FIG. 2 is a schematic cross-sectional view of a display module DM according to an embodiment of the disclosure.

Referring to FIG. 2, a display module DM may include a display panel DP and an input sensor INS. Although not illustrated separately in the drawing, the display device DD (see FIG. 1A) according to an embodiment of the disclosure may further include a protection member disposed on a lower surface of the display panel DP, or an anti-reflection member and/or a window member disposed on an upper surface of the input sensor INS.

The display panel DP may be an emission-type display panel. However, this is an example, and an embodiment of the disclosure is not limited thereto. For example, the display panel DP may be an organic light-emitting display panel or an inorganic light-emitting display panel. A light-emitting layer in the organic light-emitting display panel may include an organic light-emitting material. A light-emitting layer in the inorganic light-emitting display panel may include quantum dots, quantum rods, or a micro-LED. Hereinafter, the display panel DP is described as the organic light-emitting display panel.

The display panel DP may include a base layer BL, a circuit element layer DP-CL disposed on the base layer BL, a display element layer DP-OLED, and/or a thin-film encapsulation layer TFE. The input sensor INS may be directly disposed on the thin-film encapsulation layer TFE. In this specification, “component A directly disposed on component B” means that there is no intervening adhesive layer disposed between component A and component B.

The base layer BL may include at least one plastic film. The base layer BL, which may be a flexible substrate, may include a plastic substrate, a glass substrate, a metal substrate, an organic/inorganic composite material substrate, or the like. The display region DA and the non-display region NDA, described with reference to FIG. 1B, may be substantially equally defined in the base layer BL.

The circuit element layer DP-CL may include at least one insulation layer and a circuit element. The insulation layer may include at least one inorganic layer and at least one organic layer. The circuit element may include signal lines, a driving circuit of a pixel, etc.

The display element layer DP-OLED may include a partition wall and a light-emitting element. The light-emitting element may include an anode, an intermediate layer, and a cathode.

The thin-film encapsulation layer TFE may include thin films. Some thin films may be disposed in order to improve optical efficiency, and other thin films may be disposed in order to protect organic light-emitting diodes.

The input sensor INS acquires coordinate information on an external input. The input sensor INS may have a multi-layer structure. The input sensor INS may include a single-layer or multi-layer conductive layer. The input sensor INS may include a single-layer or multi-layer insulation layer. The input sensor INS may detect the external input in a capacitive manner. However, this is an example, and an embodiment of the disclosure is not limited thereto. For example, in an embodiment, the input sensor INS may also detect the external input in an electromagnetic induction or pressure-sensing manner. According to another embodiment of the disclosure, the input sensor INS may be omitted.

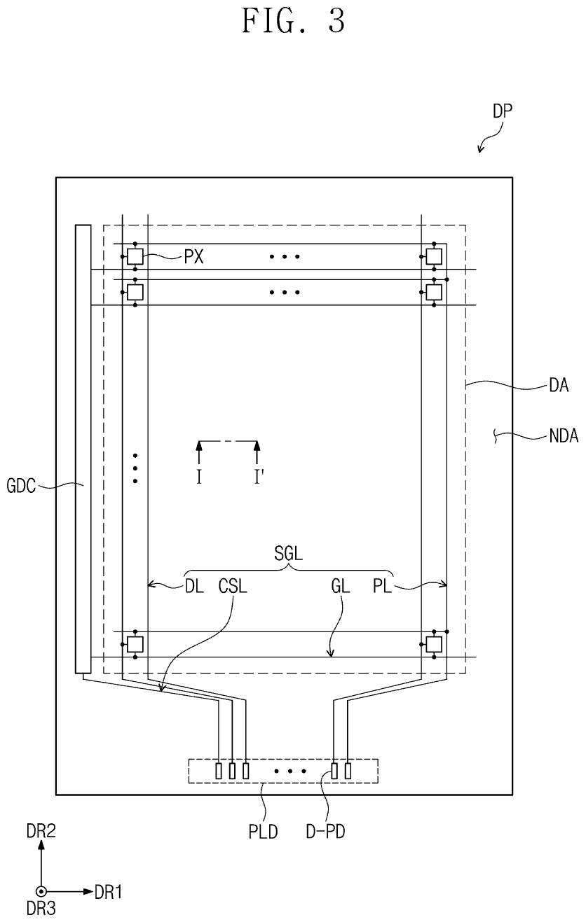

FIG. 3 is a schematic plan view of a display panel according to an embodiment of the disclosure.

Referring to FIG. 3, a display region DA and a non-display region NDA around the display region DA may be defined in the display panel DP. The display panel DP may include pixels PX and signal lines SGL electrically connected to the pixels PX. The display panel DP may include a driving circuit GDC and a pad portion PLD. The display region DA and the non-display region NDA may be distinguished according to whether the pixels PX are disposed or not. The pixels PX may be disposed in the display region DA. The driving circuit GDC and the pad portion PLD may be disposed in the non-display region NDA.

The pixels PX may be arranged in a first direction DR1 and a second direction DR2. The pixels PX may include pixel rows extending in the first direction DR1 and arranged in the second direction DR2, and pixel columns extending in the second direction DR2 and arranged in the first direction DR1.

The signal lines SGL may include gate lines GL, data lines DL, a power line PL, and/or a control signal line CSL. The gate lines GL may each be connected to a corresponding pixel PX among the pixels PX, and the data lines DL may each be connected to a corresponding pixel PX among the pixels PX. The power line PL may be electrically connected to the pixels PX. The control signal line CSL may be connected to the driving circuit GDC and provide control signals to the driving circuit GDC.

The driving circuit GDC may include a gate driving circuit. The gate driving circuit may generate gate signals, and may output the generated gate signals to the gate lines GL in sequence. The gate driving circuit may further output another control signal to a pixel driving circuit.

The pad portion PLD may be a portion where a flexible circuit board is connected. The pad portion PLD may include pixel pads D-PD, and the pixel pads D-PD may be pads for connecting the flexible circuit board to the display panel DP. The pixel pads D-PD may each be connected to a corresponding signal line among the signal lines SGL. The pixel pads D-PD may be connected to corresponding pixels PX through the signal lines SGL. Any one pixel pad among the pixel pads D-PD may be connected to the driving circuit GDC.

The pad portion PLD may further include input pads. The input pads may be pads for connecting the flexible circuit board to the input sensor INS (see FIG. 2). However, an embodiment of the disclosure is not limited thereto, and the input pads may be disposed on the input sensor INS (see FIG. 2), and may be connected to a circuit board separately from the pixel pads D-PD. As another example, the input sensor INS (see FIG. 2) may be omitted, and may not further include the input pads.

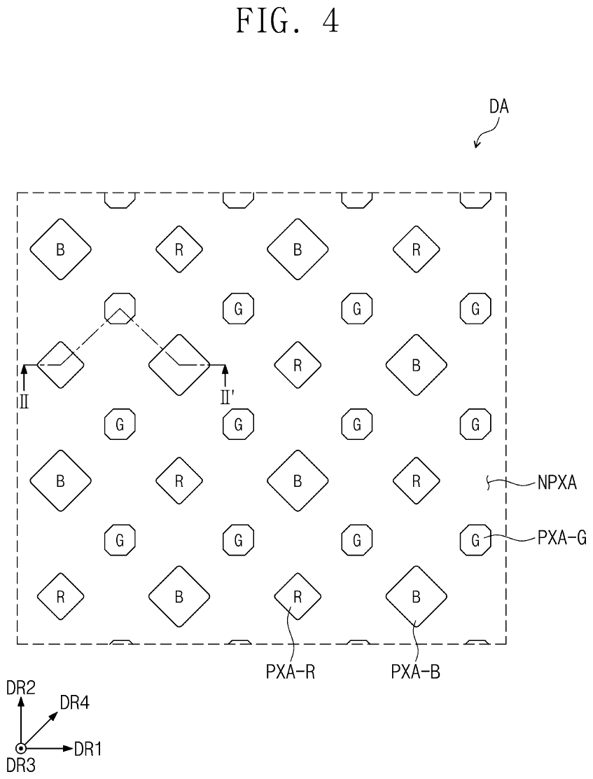

FIG. 4 is a schematic enlarged plan view illustrating a portion of a display region DA of the display panel DP (see FIG. 2) according to an embodiment of the disclosure. FIG. 4 illustrates a schematic plan view of a display module DM when viewed on the display surface IS (see FIG. 1B) of the display module DM (see FIG. 1B), and illustrates an arrangement of light-emitting regions PXA-R, PXA-G, and PXA-B.

Referring to FIG. 4, a display region DA may include first to third light-emitting regions PXA-R, PXA-G, and PXA-B, and a peripheral region NPXA surrounding the first to third light-emitting regions PXA-R, PXA-G, and PXA-B. The first to third light-emitting regions PXA-R, PXA-G, and PXA-B may respectively correspond to regions where light provided from the light-emitting elements is emitted. The first to third light-emitting regions PXA-R, PXA-G, and PXA-B may be distinguished according to colors of light emitted toward the outside of the display module DM (see FIG. 2).

The first to third light-emitting regions PXA-R, PXA-G, and PXA-B may respectively provide first to third color light having different colors from each other. For example, the first color light may be red light, the second color light may be green light, and the third color light may be blue light. However, the examples of the first to third color light are not limited thereto.

The first to third light-emitting regions PXA-R, PXA-G, and PXA-B may each be defined as a region where an upper surface of an anode is exposed by a light-emitting opening to be described below. The peripheral region NPXA may set boundaries of the first to third light-emitting regions PXA-R, PXA-G, and PXA-B, and may prevent color mixing between the first to third light-emitting regions PXA-R, PXA-G, and PXA-B.

The first to third light-emitting regions PXA-R, PXA-G, and PXA-B may each be provided in a plurality, and may be repeatedly disposed in a form (e.g., a predetermined or selectable form) of arrangement within the display region DA. For example, the first and third light-emitting regions PXA-R and PXA-B may be alternately arranged in the first direction DR1 to form a ‘first group’. The second light-emitting regions PXA-G may be arranged in the first direction DR1 to form a ‘second group’. The ‘first group’ and the ‘second group’ may each be provided in a plurality, and the ‘first groups’ and the ‘second groups’ may be alternately arranged in the second direction DR2.

A second light-emitting region PXA-G may be disposed apart from a first light-emitting region PXA-R or a third light-emitting region PXA-B in a fourth direction DR4. The fourth direction DR4 may be defined as a direction between the first and second directions DR1 and DR2.

FIG. 4 illustrates the arrangement form of the first to third light-emitting regions PXA-R, PXA-G, and PXA-B. However, an embodiment of the disclosure is not limited thereto, and the arrangement form may vary. In an embodiment, the first to third light-emitting regions PXA-R, PXA-G, and PXA-B may have a PENTILE™ arrangement form as illustrated in FIG. 4. As another example, the first to third light-emitting regions PXA-R, PXA-G, and PXA-B may also have a stripe arrangement form, or a Diamond Pixel™ arrangement form.

The first to third light-emitting regions PXA-R, PXA-G, and PXA-B may have various shapes on a plane. For example, the first to third light-emitting regions PXA-R, PXA-G, and PXA-B may have a polygon, circle, oval, or the like. FIG. 4 illustrates the first and third light-emitting regions PXA-R and PXA-B in a quadrilateral shape (or diamond shape), and the second light-emitting region PXA-G in an octagonal shape on a plane.

The first to third light-emitting regions PXA-R, PXA-G, and PXA-B may have substantially the same shape on a plane, and As another example, at least some thereof may also have different shapes on a plane. FIG. 4 illustrates the first and third light-emitting regions PXA-R and PXA-B having substantially the same shape on a plane, and the second light-emitting region PXA-G having a different shape from the first and third light-emitting regions PXA-R and PXA-B on a plane.

At least some among the first to third light-emitting regions PXA-R, PXA-G, and PXA-B may have different areas on a plane. In an embodiment, the area of the first light-emitting region PXA-R that emits the red light may be larger than the area of the second light-emitting region PXA-G that emits the green light, and may be smaller than the area of the third light-emitting region PXA-B that emits the blue light. However, the size relationship of the areas between the first to third light-emitting regions PXA-R, PXA-G, and PXA-B, according to light-emitting colors, is not limited thereto, and may vary depending on the design of the display module DM (see FIG. 2). An embodiment of the disclosure is not limited thereto, and the first to third light-emitting regions PXA-R, PXA-G, and PXA-B may also have substantially the same area on a plane.

The shape, the area, and the arrangement of the first to third light-emitting regions PXA-R, PXA-G, and PXA-B of the display module DM (see FIG. 2), according to an embodiment of the disclosure, may be variously designed according to the color of light emitted, or the size or composition of the display module DM (see FIG. 2), and are not limited to the embodiment illustrated in FIG. 4.

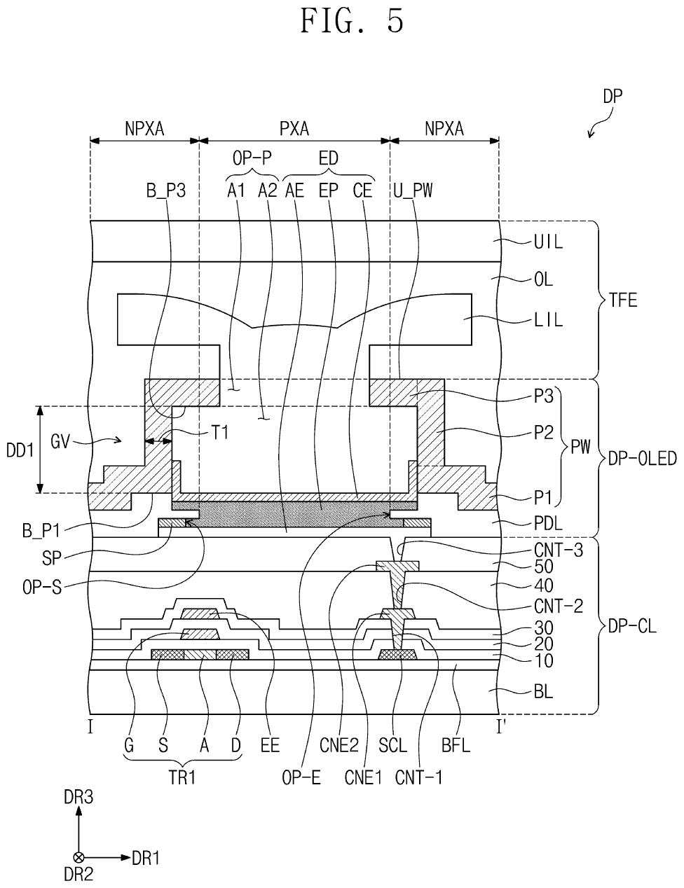

FIG. 5 is a schematic cross-sectional view of a display panel DP taken along line I-I′ of FIG. 3. In describing with reference to FIG. 5, the description with reference to FIG. 2 will be applied to FIG. 5, and the descriptions on the same reference numerals or symbols will be omitted. FIG. 5 is a schematic enlarged view of a light-emitting region PXA in the display region DA (see FIG. 4), and the light-emitting region PXA in FIG. 5 may correspond to any one among the first to third light-emitting regions PXA-R, PXA-G, and PXA-B in FIG. 4.

Referring to FIG. 5, a display panel DP may include a base layer BL, a circuit element layer DP-CL, a display element layer DP-OLED, and/or a thin-film encapsulation layer TFE.

The display panel DP may include insulation layers, a semiconductor pattern, a conductive pattern, signal lines, etc. The insulation layer, a semiconductor layer, and a conductive layer may be formed through various methods including coating, deposition, etc. After this, the insulation layer, the semiconductor layer, and the conductive layer may be selectively patterned through photolithography and/or etching. In such ways, the semiconductor pattern, the conductive pattern, the signal line, etc., included in the circuit element layer DP-CL and the display element layer DP-OLED, may be formed.

The circuit element layer DP-CL may be disposed on the base layer BL. The circuit element layer DP-CL may include a buffer layer BFL, a transistor TR1, a signal transmission region SCL, first to fifth insulation layers 10, 20, 30, 40, and 50, an electrode EE, and connection electrodes CNE1 and CNE2.

The buffer layer BFL may be disposed on the base layer BL. The buffer layer BFL may improve bonding forces between the base layer BL and a semiconductor pattern. The buffer layer BFL may include a silicon oxide layer and a silicon nitride layer. The silicon oxide layer and the silicon nitride layer may be alternately stacked each other.

A semiconductor pattern may be disposed on the buffer layer BFL. The semiconductor pattern may include polysilicon. However, an embodiment of the disclosure is not limited thereto, and the semiconductor pattern may also include amorphous silicon or metal oxide. FIG. 5 illustrates only a partial semiconductor pattern, and the semiconductor pattern may further be disposed in the light-emitting regions PXA-R, PXA-G, and PXA-B (see FIG. 4). The semiconductor pattern may be arranged in a certain rule across the light-emitting regions PXA-R, PXA-G, and PXA-B. The semiconductor pattern may have a different electrical property according to whether it is doped or not. The semiconductor pattern may include a first region doped with a high concentration and a second region doped with a low concentration. The first region may be doped with an N-type dopant or a P-type dopant. A P-type transistor may include the first region doped with a P-type dopant.

The first region may have higher conductivity than the conductivity of the second region, and may substantially serve as an electrode or a signal line. The second region may substantially correspond to an active (or channel) of the transistor. In other words, a portion of the semiconductor pattern may be the active of the transistor, another portion thereof may be a source or a drain of the transistor, and another portion thereof may be a conductive region.

A source S, an active A, and a drain D of the transistor TR1 may be formed from the semiconductor pattern. FIG. 5 illustrates a portion of the signal transmission region SCL formed from the semiconductor pattern. Although not illustrated separately in the drawing, the signal transmission region SCL may be connected to the drain D of the transistor TR1 on a plane.

The first to fifth insulation layers 10, 20, 30, 40, and 50 may be disposed on the buffer layer BFL. The first to fifth insulation layers 10, 20, 30, 40, and 50 may be an inorganic layer or an organic layer.

The first insulation layer 10 may be disposed on the buffer layer BFL. The first insulation layer 10 may cover the source S, the active A, and the drain D of the transistor TR1, and the signal transmission region SCL disposed on the buffer layer BFL. A gate G of the transistor TR1 may be disposed on the first insulation layer 10. The second insulation layer 20 may be disposed on the first insulation layer 10 to cover the gate G. The electrode EE may be disposed on the second insulation layer 20. The third insulation layer 30 may be disposed on the second insulation layer 20 to cover the electrode EE.

The first connection electrode CNE1 may be disposed on the third insulation layer 30. The first connection electrode CNE1 may be connected to the signal transmission region SCL through a contact hole CNT-1 passing through the first to third insulation layers 10, 20, and 30. The fourth insulation layer 40 may be disposed on the third insulation layer 30 to cover the first connection electrode CNE1. The fourth insulation layer 40 may be an organic layer.

The second connection electrode CNE2 may be disposed on the fourth insulation layer 40. The second connection electrode CNE2 may be connected to the first connection electrode CNE1 through a contact hole CNT-2 passing through the fourth insulation layer 40. The fifth insulation layer 50 may be disposed on the fourth insulation layer 40 to cover the second connection electrode CNE2. The fifth insulation layer 50 may be an organic layer.

The display element layer DP-OLED may be disposed on the circuit element layer DP-CL. The display element layer DP-OLED may include a light-emitting element ED, a sacrifice pattern SP, a pixel-defining film PDL, and/or a partition wall PW.

The light-emitting element ED may include an anode AE (or first electrode), a light-emitting pattern EP, and a cathode CE (or second electrode). The light-emitting element ED may be disposed inside a light-emitting opening OP-E and a partition wall opening OP-P to be described below.

The anode AE may be disposed on the fifth insulation layer 50 of the circuit element layer DP-CL. The anode AE may be a transmissive electrode, a transflective electrode, or a reflective electrode. The anode AE may be connected to the second connection electrode CNE2 through a connection contact hole CNT-3 defined by passing through the fifth insulation layer 50. Therefore, the anode AE may be electrically connected to the signal transmission region SCL through the first and second connection electrodes CNE1 and CNE2, and thus may be electrically connected to a corresponding circuit element. The anode AE may include a single-layer or multi-layer structure. The anode AE may include layers containing ITO and Ag. For example, the anode AE may include an ITO-containing layer (hereinafter, lower ITO layer), an Ag-containing layer disposed on the lower ITO layer (hereinafter, Ag layer), and an ITO-containing layer disposed on the Ag layer (hereinafter, upper ITO layer).

The sacrifice pattern SP may be disposed between the anode AE and the pixel-defining film PDL. A sacrifice opening OP-S that exposes a portion of an upper surface of the anode AE may be defined (or included) in the sacrifice pattern SP. The sacrifice opening OP-S may overlap the light-emitting opening OP-E to be described below.

The pixel-defining film PDL may be disposed on the fifth insulation layer 50 of the circuit element layer DP-CL. The light-emitting opening OP-E may be defined (or included) in the pixel-defining film PDL. The light-emitting opening OP-E may correspond to the anode AE, and the pixel-defining film PDL may expose at least a portion of the anode AE through the light-emitting opening OP-E.

The light-emitting opening OP-E may correspond to the sacrifice opening OP-S of the sacrifice pattern SP. According to this embodiment, the upper surface of the anode AE may be spaced apart from the pixel-defining film PDL with the sacrifice pattern SP therebetween on a cross-section, and accordingly, it may be possible to protect the anode AE from being damaged in a process of forming the light-emitting opening OP-E.

On a plane, the area of the light-emitting opening OP-E may be smaller than the area of the sacrifice opening OP-S. For example, an inner side surface of the pixel-defining film PDL defining the light-emitting opening OP-E may be more adjacent to the center of the anode AE than an inner side surface of the sacrifice pattern SP defining the sacrifice opening OP-S. However, an embodiment of the disclosure is not limited thereto, and the inner side surface of the sacrifice pattern SP defining the sacrifice opening OP-S may be substantially aligned with the inner side surface of the pixel-defining film PDL defining the light-emitting opening OP-E. In this case, the light-emitting region PXA may also be regarded as a region of the anode AE exposed from the corresponding sacrifice opening OP-S.

The pixel-defining film PDL may include an inorganic insulating material. For example, the pixel-defining film PDL may include silicon nitride (SiNx). The pixel-defining film PDL may be disposed between the anode AE and the partition wall PW, and may thus prevent the anode AE and the partition wall PW from being electrically connected to each other.

The light-emitting pattern EP may be disposed on the anode AE. The light-emitting pattern EP may include a light-emitting layer containing a light-emitting material. The light-emitting pattern EP may further include a hole injection layer HIL and a hole transport layer HTL disposed between the anode AE and the light-emitting layer, and may also further include an electron transport layer ETL and an electron injection layer EIL disposed on the light-emitting layer. The light-emitting pattern EP may also be referred to as an ‘intermediate layer’.

The light-emitting pattern EP may be patterned by a tip portion defined on the partition wall PW. Details thereof will be described below in a description of a manufacturing method for a display panel. The light-emitting pattern EP may be disposed inside the sacrifice opening OP-S and the light-emitting opening OP-E. However, this is illustrated as an example, and the light-emitting pattern EP may be disposed inside at least one opening of the sacrifice opening OP-S, the light-emitting opening OP-E, and the partition wall opening OP-P. The light-emitting pattern EP may cover a portion of an upper surface of the pixel-defining film PDL.

The cathode CE may be disposed on the light-emitting pattern EP. The cathode CE may be patterned by the tip portion defined on the partition wall PW. At least a portion of the cathode CE may be disposed in the partition wall opening OP-P. FIG. 5 illustrates that the cathode CE is disposed inside the light-emitting opening OP-E and the partition wall opening OP-P as an example, but an embodiment of the disclosure is not limited thereto. For example, the cathode CE may be disposed only inside the partition wall opening OP-P.

The cathode CE may extend along an inner side surface of the partition wall PW, and an end portion of the cathode CE may contact the partition wall PW. FIG. 5 illustrates that the cathode CE contacts the inner side surface of the partition wall PW and the inner side surface of the pixel-defining film PDL, but an embodiment of the disclosure is not limited thereto. For example, the cathode CE may contact only the inner side surface of the partition wall PW.

The cathode CE may have conductivity. The cathode CE may be formed of various materials, such as metal, transparent conductive oxide (TCO), or a conductive polymer material, as long as it has conductivity. For example, the cathode CE may include silver (Ag), magnesium (Mg), lead (Pb), copper (Cu), or a compound thereof.

The partition wall PW may be disposed on the pixel-defining film PDL. The partition wall PW may include a conductive material. For example, the conductive material may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy thereof. The transparent conductive oxide may include indium tin oxide (ITO), indium zinc oxide (IZO), zinc oxide, indium oxide, indium gallium oxide, indium gallium zinc oxide (IGZO), or aluminum zinc oxide. In an embodiment, the partition wall PW may include at least one of molybdenum (Mo), tungsten (W), and a molybdenum-tungsten (Mo—W) alloy.

The partition wall PW including the conductive material may receive a driving voltage, and accordingly, the cathode CE may be electrically connected to the partition wall PW to receive the driving voltage.

The partition wall PW may have an undercut shape on a cross-section. The partition wall PW may include first portions P1, second portions P2, and third portions P3. The first portions P1 of the partition wall PW may be disposed on the pixel-defining film PDL. The second portions P2 of the partition wall PW may extend from the first portions P1 in the thickness direction of the base layer BL (for example, the opposite direction of the third direction DR3). The third portions P3 of the partition wall PW may extend from the second portions P2 toward the center of the partition wall opening OP-P. The partition wall PW may include tip portions. For example, the third portions P3 of the partition wall PW may protrude toward the light-emitting opening OP-E to form the tip portions. For example, the third portions P3 protruding from the second portions P2 may be defined as the tip portions (or include the tip portions). For example, inner side surfaces of the third portions P3 may be closer to the center of the anode AE than inner side surfaces of the second portions P2.

The partition wall PW may have the partition wall opening OP-P and a groove GV (defined therein). The partition wall opening OP-P may overlap the light-emitting opening OP-E, and may expose at least a portion of the anode AE. The groove GV may have a concave shape from an upper surface U_PW of the partition wall PW in the thickness direction of the base layer BL (for example, the opposite direction of the third direction DR3), and the groove GV may overlap the pixel-defining film PDL on a plane.

The partition wall opening OP-P may include a first region A1 defined by the third portions P3 of the partition wall PW, and a second region A2 defined by the second portions P2 of the partition wall PW. The width of the first region A1 in a direction (for example, first direction DR1 or second direction DR2) may be smaller than the width of the second region A2 in the direction (for example, first direction DR1 or second direction DR2).

A length DD1 of the partition wall PW from lower surfaces B_P1 of the first portions P1, adjacent to the second portions P2, to lower surfaces B_P3 of the third portions P3 may be in a range of about 0.5 μm to about 1 μm. In an embodiment, the length DD1 of the partition wall PW from the lower surfaces B_P1 of the first portions P1 to the lower surfaces B_P3 of the third portions P3 may be about 0.6 μm. A thickness T1 of the partition wall PW may be in a range of about 0.2 μm to about 0.5 μm.

FIG. 5 illustrates that the inner side surfaces of the partition wall PW are perpendicular to the upper surface of the pixel-defining film PDL as an example, but an embodiment of the disclosure is not limited thereto. For example, the partition wall PW may have a tapered shape or a reversed tapered shape.

The thin-film encapsulation layer TFE may be disposed on the display element layer DP-OLED. The thin-film encapsulation layer TFE may include a lower inorganic encapsulation pattern LIL, an organic encapsulation film OL, and/or an upper inorganic encapsulation film UIL.

The lower inorganic encapsulation pattern LIL may correspond to (or overlap) the light-emitting opening OP-E. The lower inorganic encapsulation pattern LIL may be disposed on the light-emitting element ED to cover the light-emitting element ED. A portion of the lower inorganic encapsulation pattern LIL may be formed in the partition wall opening OP-P, and another portion of the lower inorganic encapsulation pattern LIL may be formed above the partition wall PW. For example, the portion of the lower inorganic encapsulation pattern LIL may fill the partition wall opening OP-P, and the another portion of the lower inorganic encapsulation pattern LIL may be formed above the partition wall PW to be spaced apart from the partition wall PW.

The organic encapsulation film OL may be disposed on the lower inorganic encapsulation pattern LIL. The organic encapsulation film OL may cover the lower inorganic encapsulation pattern LIL to provide a flat upper surface thereto. The organic encapsulation film OL may fill the groove GV of the partition wall PW. The upper inorganic encapsulation film UIL may be disposed on the organic encapsulation film OL.

The lower inorganic encapsulation pattern LIL and the upper inorganic encapsulation film UIL may protect the display element layer DP-OLED from moisture/oxygen, and the organic encapsulation film OL may protect the display element layer DP-OLED from foreign substances such as dust particles.

Molybdenum (Mo), tungsten (W), or a molybdenum-tungsten (Mo—W) alloy may have high adhesiveness and low contact resistance characteristics. However, molybdenum (Mo), tungsten (W), or a molybdenum-tungsten (Mo—W) alloy may have high stress characteristics, so that the same is required to be manufactured to have a small thickness. However, according to an embodiment of the disclosure, since the partition wall PW has a shape having the groove GV defined therein, the partition wall PW may have a large height DD1 (the length from the lower surfaces B_P1 of the first portions P1 to the lower surfaces B_P3 of the third portions P3) even in case of including molybdenum (Mo), tungsten (W), or a molybdenum-tungsten (Mo—W) alloy. For example, the display panel DP according to an embodiment of the disclosure may include the partition wall PW which has a high adhesiveness for the cathode CE and the lower inorganic encapsulation pattern LIL, a low contact resistance for the cathode, and a large height DD1. As a result, pixel defects (dark spots, pixel shrinkage, etc.) of the display panel may be reduced or eliminated.

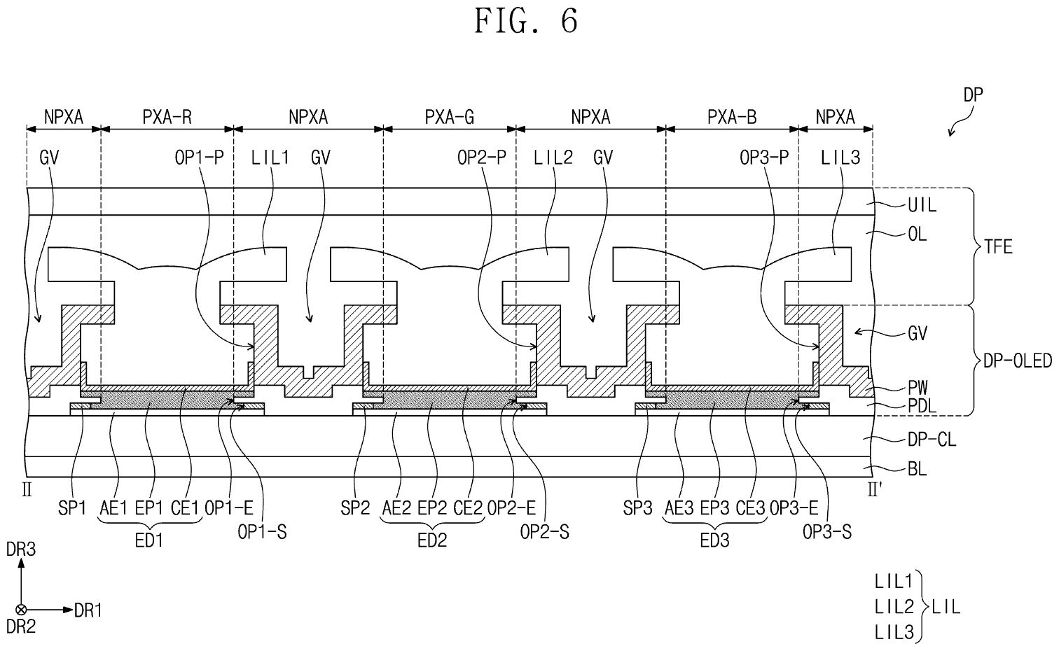

FIG. 6 is a schematic cross-sectional view taken along line II-II′ of FIG. 4. FIG. 6 is a schematic enlarged view of a first light-emitting region PXA-Ra one second light-emitting region PXA-G, and a third light-emitting region PXA-B, and the description of the light-emitting region PXA with reference to FIG. 5 may be substantially equally applied to each of the first to third light-emitting regions PXA-R, PXA-G, and PXA-B in FIG. 6. In describing with reference to FIG. 6, same/similar components as/with the components described with reference to FIG. 5 are denoted as the same/similar reference numerals or symbols, and duplicate descriptions are omitted.

Referring to FIG. 6, a display panel DP may include a base layer BL, a circuit element layer DP-CL, a display element layer DP-OLED, and a thin-film encapsulation layer TFE. The display element layer DP-OLED may include light-emitting elements ED1, ED2, and ED3, sacrifice patterns SP1, SP2, and SP3, a pixel-defining film PDL, and/or a partition wall PW.

The light-emitting elements ED1, ED2, and ED3 may include a first light-emitting element ED1, a second light-emitting element ED2, and a third light-emitting element ED3 that emit light of different colors. The first light-emitting element ED1, the second light-emitting element ED2, and the third light-emitting element ED3 may be provided in a plurality.

The first light-emitting element ED1 may include a first anode AE1, a first light-emitting pattern EP1, and a first cathode CE1. The second light-emitting element ED2 may include a second anode AE2, a second light-emitting pattern EP2, and a second cathode CE2. The third light-emitting element ED3 may include a third anode AE3, a third light-emitting pattern EP3, and a third cathode CE3. The first to third anodes AE1, AE2, and AE3 may be provided in patterns. In an embodiment, the first light-emitting pattern EP1 may provide red light, the second light-emitting pattern EP2 may provide green light, and the third light-emitting pattern EP3 may provide blue light.

First to third light-emitting openings OP1-E, OP2-E, and OP3-E may be defined in the pixel-defining film PDL. The first light-emitting opening OP1-E may expose at least a portion of the first anode AE1. The second light-emitting opening OP2-E may expose at least a portion of the second anode AE2. The third light-emitting opening OP3-E may expose at least a portion of the third anode AE3.

According to an embodiment of the disclosure, the first light-emitting region PXA-R may be defined as a region of an upper surface of the first anode AE1 exposed by the first light-emitting opening OP1-E. The second light-emitting region PXA-G may be defined as a region of an upper surface of the second anode AE2 exposed by the second light-emitting opening OP2-E. The third light-emitting region PXA-B may be defined as a region of an upper surface of the third anode AE3 exposed by the third light-emitting opening OP3-E.

According to an embodiment of the disclosure, the sacrifice patterns SP1, SP2, and SP3 may include a first sacrifice pattern SP1, a second sacrifice pattern SP2, and a third sacrifice pattern SP3. The first to third sacrifice patterns SP1, SP2, and SP3 may be respectively disposed on the upper surfaces of the first to third anodes AE1, AE2, and AE3. First to third sacrifice openings OP1-S, OP2-S, and OP3-S, respectively overlapping the first to third light-emitting openings OP1-E, OP2-E, and OP3-E, may be defined in the first to third sacrifice patterns SP1, SP2, and SP3.

First to third partition wall openings OP1-P, OP2-P, and OP3-P and a groove GV may be defined in the partition wall PW. The first to third partition wall openings OP1-P, OP2-P, and OP3-P may respectively overlap the first to third light-emitting openings OP1-E, OP2-E, and OP3-E, and the groove GV may overlap the pixel-defining film PDL. The groove GV may be formed between the first to third partition wall openings OP1-P, OP2-P, and OP3-P on a plane. For example, a portion of the groove GV may be formed between the first partition wall opening OP1-P and the second partition wall opening OP2-P on a plane, a portion of the groove GV may be formed between the second partition wall opening OP2-P and the third partition wall opening OP3-P on a plane, and a portion of the groove GV may be formed between the third partition wall opening OP3-P and the first partition wall opening OP1-P on a plane.

According to an embodiment of the disclosure, the first to third light-emitting patterns EP1, EP2, and EP3 and the first to third cathodes CE1, CE2, and CE3 may be physically separated by the partition wall PW that forms a tip portion, and may thus be respectively formed in the light-emitting openings OP1-E, OP2-E, and OP3-E, and in the partition wall openings OP1-P, OP2-P, and OP3-P. For example, the light-emitting elements ED1, ED2, and ED3 may be disposed in the partition wall openings OP1-P, OP2-P, and OP3-P and the light-emitting openings OP1-E, OP2-E, and OP3-E. For example, the first light-emitting element ED1 may be disposed in the first partition wall opening OP1-P and the first light-emitting opening OP1-E, the second light-emitting element ED2 may be disposed in the second partition wall opening OP2-P and the second light-emitting opening OP2-E, and the third light-emitting element ED3 may be disposed in the third partition wall opening OP3-P and the third light-emitting opening OP3-E.

According to an embodiment of the disclosure, first light-emitting patterns EP1 may be patterned and deposited on a pixel-by-pixel basis by the tip portion which is defined in the partition wall PW. For example, the first light-emitting patterns EP1 may be formed in common using an open mask, but may be readily separated into pixel units by the partition wall PW.

On the other hand, in case of patterning the first light-emitting patterns EP1 using a fine metal mask (FMM), a supporting spacer protruding from a conductive partition wall may need to be provided in order to support the fine metal mask. Since the fine metal mask is spaced apart by the height of the partition wall and the spacer from a base surface on which the patterning is performed, there may be a limitation in achieving high resolution. Since the fine metal mask contacts the spacer, foreign substances may remain on the spacer after the patterning of the first light-emitting patterns EP1, or the spacer may be damaged due to stamping of the fine metal mask. Accordingly, a display panel may be formed with defects.

According to this embodiment, by including the partition wall PW, the light-emitting elements ED1, ED2, and ED3 may be physically separated with ease. Accordingly, leakage current, driving error, or the like between the light-emitting regions PXA-R, PXA-G, and PXA-B adjacent to each other may be prevented, and it may be possible for each of the light-emitting elements ED1, ED2, and ED3 to operate independently.

In particular, by patterning the first light-emitting patterns EP1 without a mask contacting components inside the display region DA (see FIG. 1B), the defect rate may be reduced, so that the display panel DP with improved process reliability may be provided. Since the patterning may be possible even without a separate supporting spacer protruding from the partition wall PW, the areas of the light-emitting regions PXA-R, PXA-G, and PXA-B may be miniaturized, thereby providing the display panel DP that may readily achieve high resolution.

In manufacturing a large-area display panel DP, since the manufacturing of a large-area mask may be omitted, the process cost may be lowered, and defects, which might occur on the large-area mask, may not affect the process, it may be possible to provide the display panel DP with improved process reliability. The description on the first light-emitting patterns EP1 may also be substantially equally applied to the second and third light-emitting patterns EP2 and EP3.

The thin-film encapsulation layer TFE may include lower inorganic encapsulation patterns LIL, an organic encapsulation film OL, and/or an upper inorganic encapsulation film UIL.

The lower inorganic encapsulation patterns LIL may include a first lower inorganic encapsulation pattern LIL1 that covers the first light-emitting element ED1, a second lower inorganic encapsulation pattern LIL2 that covers the second light-emitting element ED2, and a third lower inorganic encapsulation pattern LIL3 that covers the third light-emitting element ED3. The first to third lower inorganic encapsulation patterns LIL1, LIL2, and LIL3 may respectively overlap the first to third light-emitting openings OP1-E, OP2-E, and OP3-E. The first to third lower inorganic encapsulation patterns LIL1, LIL2, and LIL3 may be provided in patterns spaced apart from each other.

A portion of the first lower inorganic encapsulation pattern LIL1 may fill the first partition wall opening OP1-P, and another portion of the first lower inorganic encapsulation pattern LIL1 may be formed apart from the partition wall PW above the partition wall PW. A portion of the second lower inorganic encapsulation pattern LIL2 may fill the second partition wall opening OP2-P, and another portion of the second lower inorganic encapsulation pattern LIL2 may be formed apart from the partition wall PW above the partition wall PW. A portion of the third lower inorganic encapsulation pattern LIL3 may fill the third partition wall opening OP3-P, and another portion of the third lower inorganic encapsulation pattern LIL3 may be formed apart from the partition wall PW above the partition wall PW.

The organic encapsulation film OL may be disposed on the first to third lower inorganic encapsulation patterns LIL1, LIL2, and LIL3. The organic encapsulation film OL may cover the first to third lower inorganic encapsulation patterns LIL1, LIL2, and LIL3 and provide a flat upper surface. The organic encapsulation film OL may fill the groove GV of the partition wall PW.

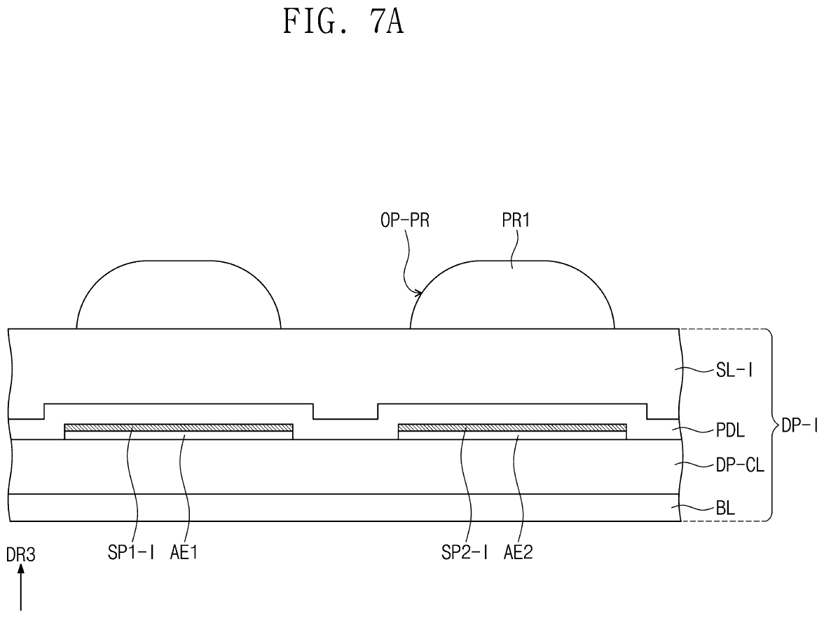

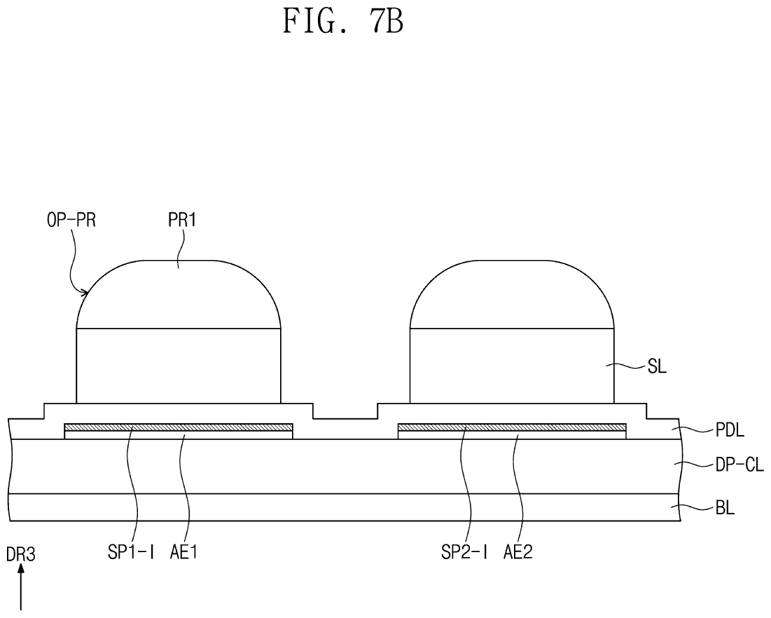

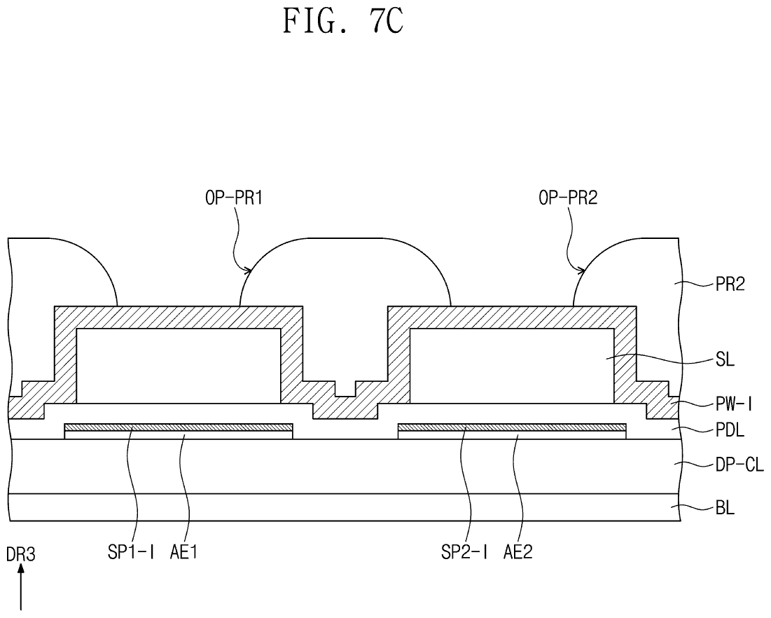

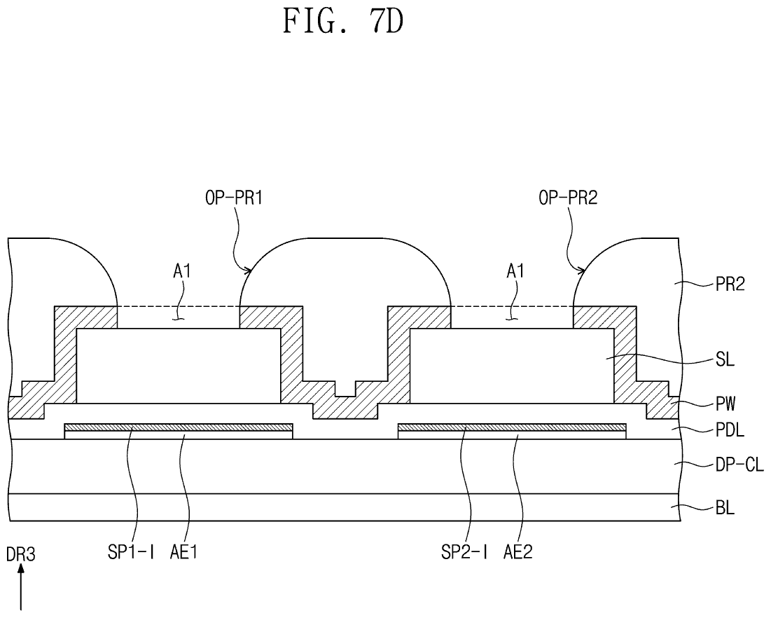

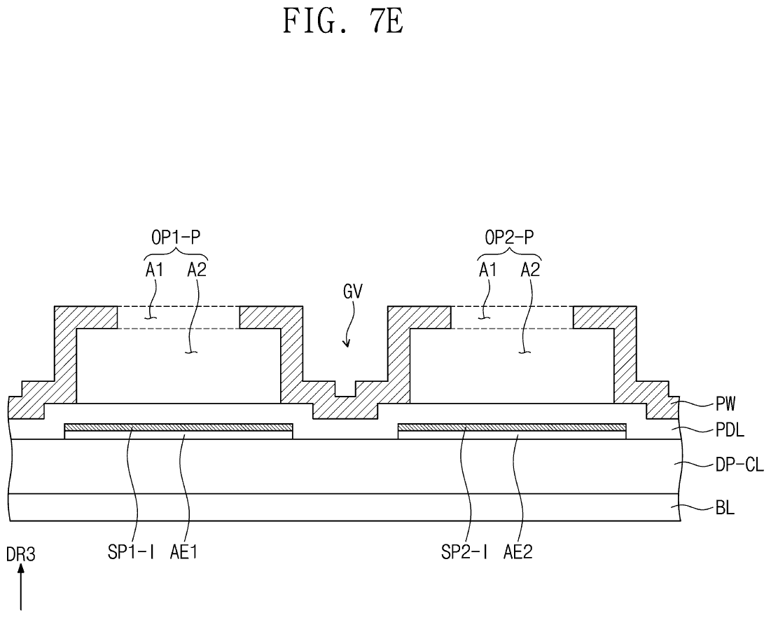

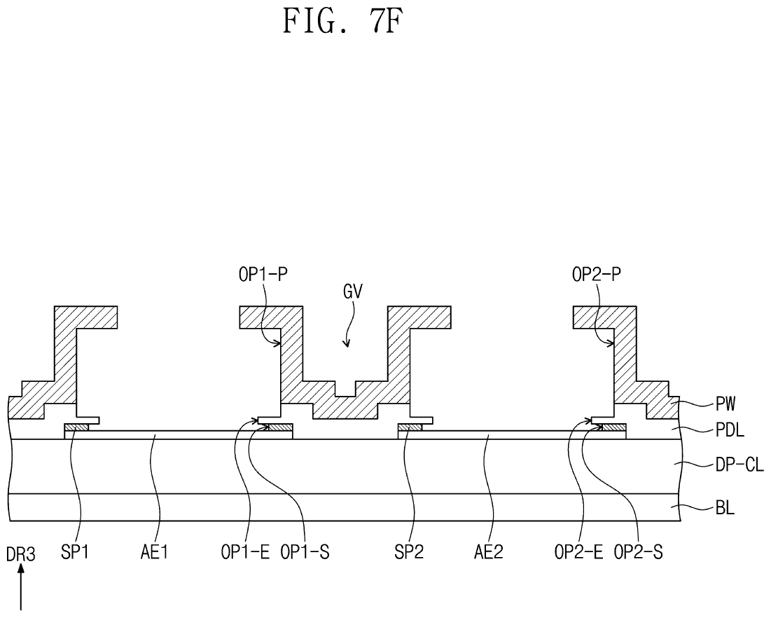

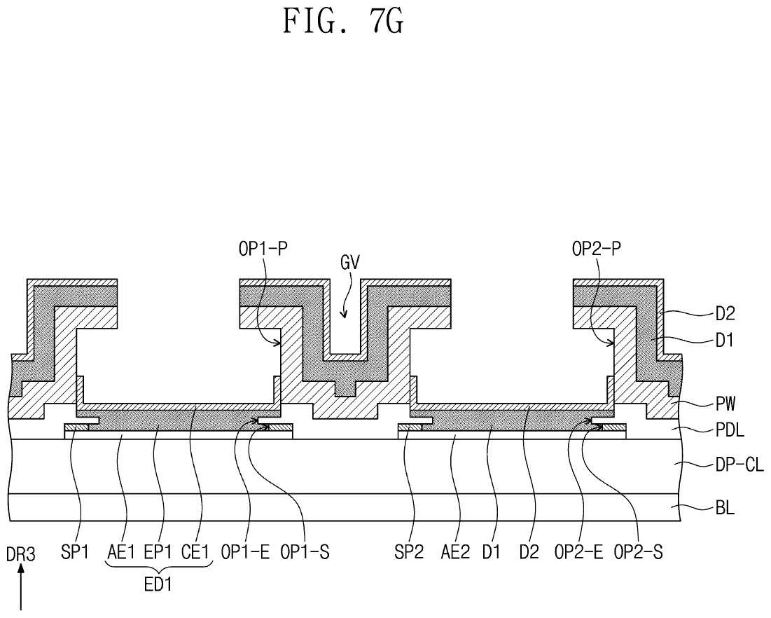

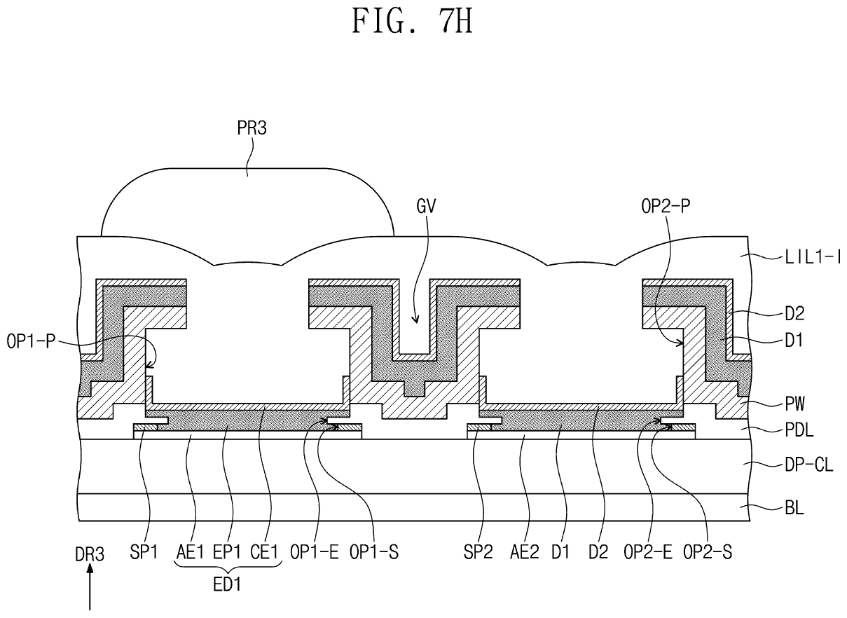

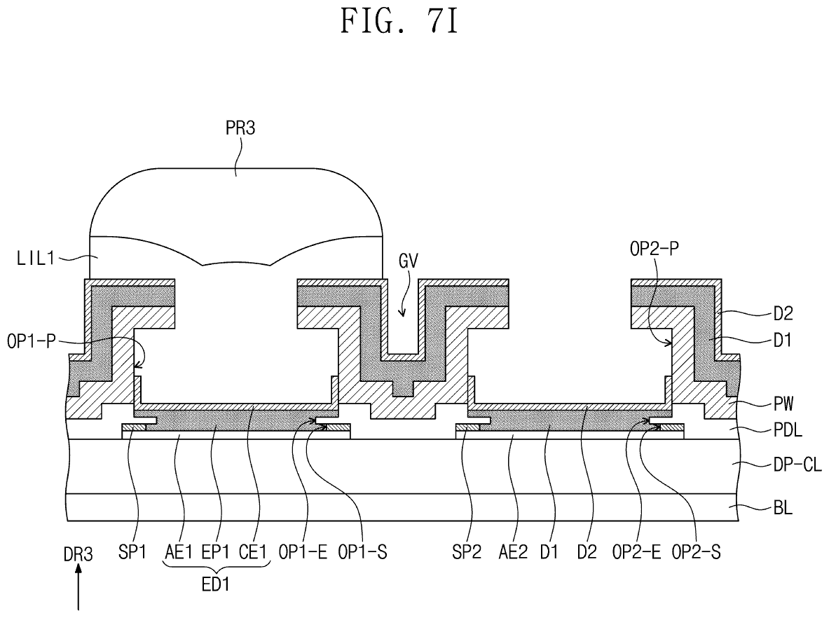

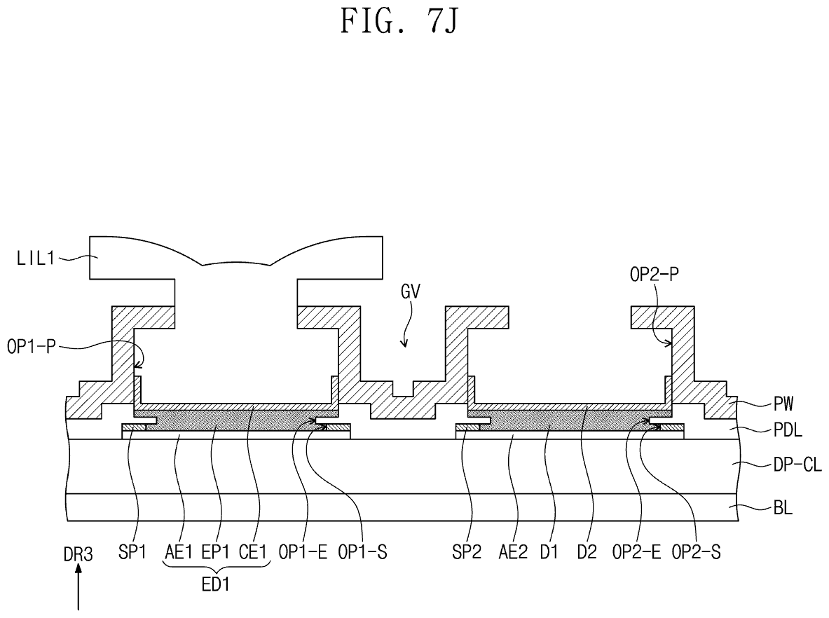

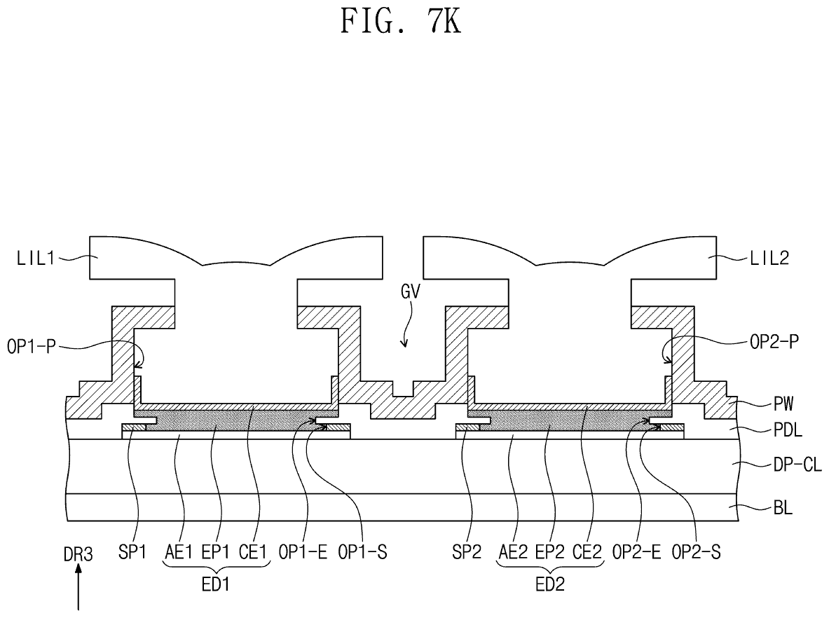

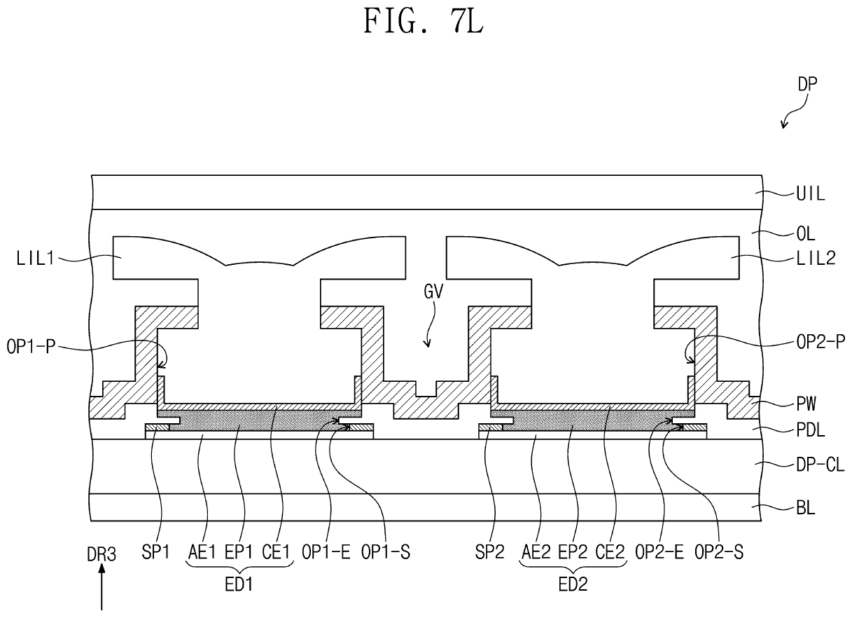

FIGS. 7A to 7L are schematic cross-sectional views illustrating some steps of a manufacturing method for a display panel according to an embodiment of the disclosure. In describing with reference to FIGS. 7A to 7L, same/similar components as/with the components in FIGS. 1 to 6 will be denoted as the same/similar reference numerals or symbols, and duplicate descriptions will be omitted.

A manufacturing method for a display panel, according to an embodiment of the disclosure, may include providing a preliminary display panel having a base layer, an anode disposed on the base layer, and a pixel-defining film covering the anode, forming an auxiliary layer overlapping the anode on the preliminary display panel, forming a preliminary partition wall on the pixel-defining film and the auxiliary layer, etching the preliminary partition wall and the auxiliary layer to form a partition wall including partition wall opening, etching the pixel-defining film to form a light-emitting opening overlapping the partition wall opening, and forming a light-emitting element in the light-emitting opening and the partition wall opening.

Hereinafter, with reference to FIGS. 7A to 7L, forming two light-emitting elements ED1 and ED2, lower inorganic encapsulation patterns LIL1 and LIL2 covering the light-emitting elements ED1 and ED2, an organic encapsulation film OL, and an upper inorganic encapsulation film UIL will be described. A display panel DP, formed through the illustrations in FIGS. 7A to 7L, may correspond to a portion of the display panel DP in FIG. 6.

Referring to FIG. 7A, the manufacturing method for the display panel, according to an embodiment of the disclosure, may include the step of providing a preliminary display panel DP-I. The preliminary display panel DP-I, provided according to this embodiment, may include a base layer BL, a circuit element layer DP-CL, first and second anodes AE1 and AE2, first and second preliminary sacrifice patterns SP1-I and SP2-I, a pixel-defining film PDL, and a preliminary auxiliary layer SL-I.

The circuit element layer DP-CL may be formed through a general circuit element manufacturing process in which an insulation layer, a semiconductor layer, and a conductive layer are formed through coating, deposition, etc., and the insulation layer, the semiconductor layer, and the conductive layer are selectively patterned through photolithography and an etching process to thereby form a semiconductor pattern, a conductive pattern, a signal line, and the like.

The first anode AE1 and the first preliminary sacrifice pattern SP1-I may be formed through the same patterning process, and the second anode AE2 and the second preliminary sacrifice pattern SP2-I may be formed through the same patterning process. The pixel-defining film PDL may be disposed on the base layer BL. The pixel-defining film PDL may cover all of the first and second anodes AE1 and AE2, and the first and second preliminary sacrifice patterns SP1-I and SP2-I.

The preliminary auxiliary layer SL-I may be formed by being deposited on the pixel-defining film PDL. The preliminary auxiliary layer SL-I may be a material having a high selectivity to a preliminary partition wall PW-I (see FIG. 7C) to be described below. For example, the preliminary auxiliary layer SL-I may be silicon (Si), silicon nitride (SiNx), polyimide (PI), and the like. The materials of the preliminary auxiliary layer SL-I are examples, and an embodiment of the disclosure is not limited to the examples. The height of the deposited preliminary auxiliary layer SL-I may determine the height DD1 (see FIG. 5) of a partition wall PW (see FIG. 7E) to be formed below.

The manufacturing method for the display panel, according to an embodiment of the disclosure, may include forming a first photoresist layer PR1 on the preliminary auxiliary layer SL-I. After a preliminary photoresist layer is formed on the preliminary auxiliary layer SL-I, the preliminary photoresist layer may be patterned by using a photo mask to thereby form the first photoresist layer PR1. Through the patterning process, a photo opening OP-PR may be formed in the first photoresist layer PR1. The photo opening OP-PR may not overlap the first and second anodes AE1 and AE2 on a plane.

After this, referring to FIG. 7B, the manufacturing method for the display panel, according to an embodiment of the disclosure, may include the step of forming an auxiliary layer SL overlapping the first and second anodes AE1 and AE2. In the step of forming the auxiliary layer SL, the preliminary auxiliary layer SL-I (see FIG. 7A) may be dry etched by using the first photoresist layer PR1 as a mask. A portion of the preliminary auxiliary layer SL-I not overlapping the first photoresist layer PR1 may be etched to be removed, and a portion thereof overlapping the first photoresist layer PR1 may become the auxiliary layer SL.

After this, referring to FIG. 7C, the manufacturing method for the display panel, according to an embodiment of the disclosure, may include the step of forming the preliminary partition wall PW-I on the pixel-defining film PDL and the auxiliary layer SL after removing the first photoresist layer PR1 (see FIG. 7B).

The preliminary partition wall PW-I may be disposed on the pixel-defining film PDL and the auxiliary layer SL. The preliminary partition wall PW-I may be formed through a deposition process of a conductive material. The preliminary partition wall PW-I may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy thereof. The transparent conductive oxide may include indium tin oxide (ITO), indium zinc oxide (IZO), zinc oxide, indium oxide, indium gallium oxide, indium gallium zinc oxide (IGZO), or aluminum zinc oxide. According to an embodiment of the disclosure, the step of forming the preliminary partition wall PW-I may include depositing at least one of molybdenum (Mo), tungsten (W), and a molybdenum-tungsten (Mo—W) alloy.

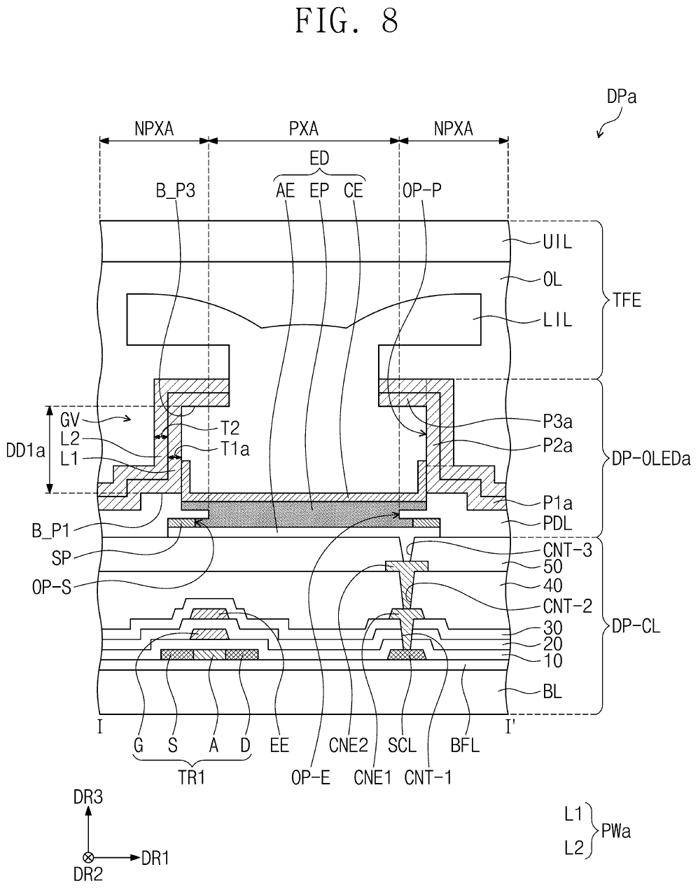

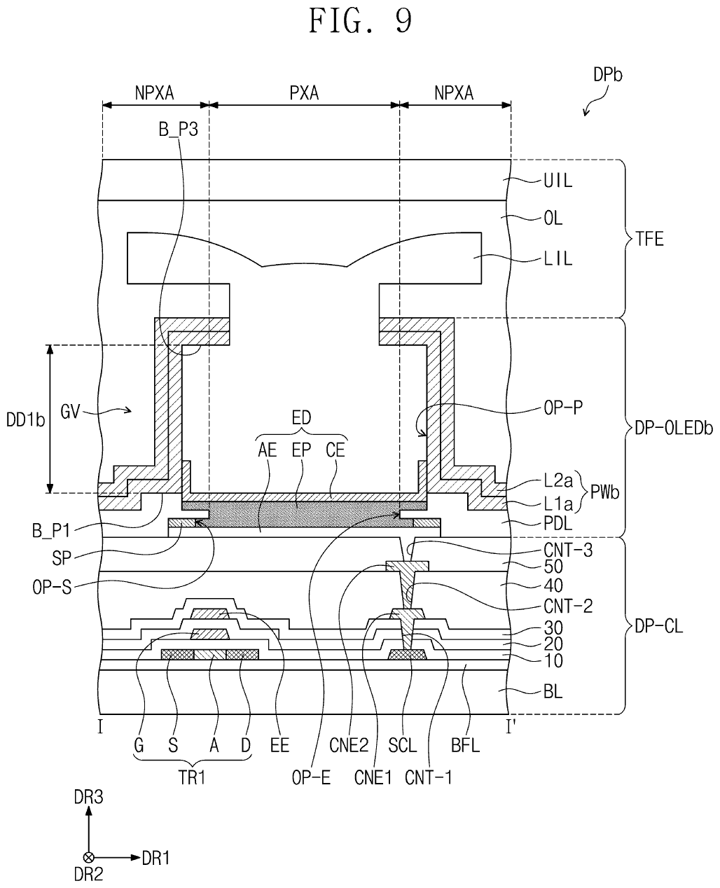

However, this is an example, and the process of forming the preliminary partition wall PW-I and the material of the preliminary partition wall PW-I are not limited to the example. For example, the step of forming the preliminary partition wall PW-I on the pixel-defining film PDL and the auxiliary layer SL may include depositing a first preliminary partition wall layer on the pixel-defining film PDL and the auxiliary layer SL, and forming a second preliminary partition wall layer on the first preliminary partition wall layer. In an embodiment, the first preliminary partition wall layer may include at least one of molybdenum (Mo), tungsten (W), and a molybdenum-tungsten (Mo—W) alloy, and the second preliminary partition wall layer may include at least one of titanium (Ti) and aluminum (Al). The display panel manufactured through the above-mentioned process may correspond to a display panel DPa or DPb in FIG. 8 or FIG. 9.

After this, the manufacturing method for the display panel, according to an embodiment of the disclosure, may include forming a second photoresist layer PR2 on the preliminary partition wall PW-I. After the preliminary photoresist layer is formed on the preliminary partition wall PW-I, the preliminary photoresist layer may be patterned by using a photo mask to thereby form the second photoresist layer PR2. Through the patterning process, a first photo opening OP-PR1 and a second photo opening OP-PR2 may be formed in the second photoresist layer PR2. The first photo opening OP-PR1 may overlap the first anode AE1, and the second photo opening OP-PR2 may overlap the second anode AE2.

After this, referring to FIGS. 7D and 7E, the manufacturing method for the display panel, according to an embodiment of the disclosure, may include the step of etching the preliminary partition wall PW-I (see FIG. 7C) and the auxiliary layer SL to form the partition wall PW including the partition wall opening OP-P. The step of etching the preliminary partition wall PW-I and the auxiliary layer SL to form the partition wall PW including the partition wall opening OP-P may include etching the preliminary partition wall PW-I to form a first region A1 of the partition wall opening OP-P, and etching the auxiliary layer SL to form a second region A2 of the partition wall opening OP-P. With reference to FIG. 7D, the step of forming the first region A1 is described, and with reference to FIG. 7E, the step of forming the second region A2 is described.

First, as illustrated in FIG. 7D, in the step of etching the preliminary partition wall PW-I to form the first region A1 of the partition wall opening OP-P (see FIG. 7E), the preliminary partition wall PW-I may be dry etched using the second photoresist layer PR2 as a mask. A portion of the preliminary partition wall PW-I not overlapping the second photoresist layer PR2 may be etched to be removed, and the first region A1 may be formed at the portion etched and removed. For example, the first region A1, corresponding to the first anode AE1, may be formed at a portion overlapping the first photo opening OP-PR1 and removed, and the first region A1, corresponding to the second anode AE2, may be formed at a portion overlapping the second photo opening OP-PR2 and removed. The partition wall PW may be formed from the preliminary partition wall PW-I where the first region A1 is defined.

After this, as illustrated in FIG. 7E, in the step of etching the auxiliary layer SL (see FIG. 7D) to form the second region A2 of the partition wall opening OP-P, after the second photoresist layer PR2 (see FIG. 7D) is removed, the auxiliary layer SL may be dry etched, and may be removed. The second region A2 may be formed at a portion thereof etched and removed. The width of the first region A1 in a direction may be smaller than the width of the second region A2 in the direction. The first region A1 and the second region A2 may define the partition wall openings OP1-P and OP2-P. For example, the first region A1 and the second region A2 overlapping the first anode AE1 may define the first partition wall opening OP1-P, and the first region A1 and the second region A2 overlapping the second anode AE2 may define the second partition wall opening OP2-P.

The etching process of forming the second region A2 may be performed in a condition where the etch selectivity between the auxiliary layer SL and the partition wall PW is large. In particular, since the etch rate of the auxiliary layer SL is larger than the etch rate of the partition wall PW for the etching solution, the auxiliary layer SL may be mainly etched.

Accordingly, the partition wall PW may have an undercut shape on a cross-section, and may include tip portions. For example, the third portions P3 (see FIG. 5) protruding from the second portions P2 (see FIG. 5) may be defined as the tip portions (or include the tip portions). For example, inner side surfaces of the third portions P3 may be closer to the center of the anode AE1 or AE2 than inner side surfaces of the second portions P2.

At a portion where the second photoresist layer PR2 is removed, the partition wall PW may include a groove GV. The groove GV may be concave from an upper surface of the partition wall PW in the thickness direction of the base layer BL (for example, the opposite direction of the third direction DR3).

After this, referring to FIG. 7F, the manufacturing method for the display panel, according to an embodiment of the disclosure, may include the step of etching the pixel-defining film PDL to form the light-emitting openings OP1-E and OP2-E overlapping the partition wall openings OP1-P and OP2-P.

In the step of etching the pixel-defining film PDL, the pixel-defining film PDL may be dry etched using the partition wall PW as a mask. A portion of the pixel-defining film PDL not overlapping the partition wall PW may be etched and removed. As a result, the light-emitting openings OP1-E and OP2-E overlapping the partition wall openings OP1-P and OP2-P may be formed in the pixel-defining film PDL. The light-emitting openings OP1-E and OP2-E may include a first light-emitting opening OP1-E overlapping the first partition wall opening OP1-P, and a second light-emitting opening OP2-E overlapping the second partition wall opening OP2-P. The etched pixel-defining film PDL may overlap the groove GV.

After this, the manufacturing method for the display panel, according to an embodiment of the disclosure, may include etching the first and second preliminary sacrifice patterns SP1-I and SP2-I (see FIG. 7E) to form sacrifice patterns SP1 and SP2 having sacrifice openings OP1-S and OP2-S overlapping the light-emitting openings OP1-E and OP2-E.

In the step of etching the first and second preliminary sacrifice patterns SP1-I and SP2-I, the first and second preliminary sacrifice patterns SP1-I and SP2-I may be wet etched using the partition wall PW as a mask. A portion of the first and second preliminary sacrifice patterns SP1-I and SP2-I not overlapping the partition wall PW may be etched and removed. As a result, the sacrifice patterns SP1 and SP2 may be formed from the first and second preliminary sacrifice patterns SP1-I and SP2-I.

The sacrifice patterns SP1 and SP2 may include a first sacrifice pattern SP1 and a second sacrifice pattern SP2. A first sacrifice opening OP1-S overlapping the first light-emitting opening OP1-E may be formed in the first sacrifice pattern SP1, and a second sacrifice opening OP2-S overlapping the second light-emitting opening OP2-E may be formed in the second sacrifice pattern SP2.

The etching process of the sacrifice patterns SP1 and SP2 may be performed in a condition where the etch selectivity between the sacrifice patterns SP1 and SP2 and the anodes AE1 and AE2 is large, thereby preventing the anodes AE1 and AE2 from being etched together. For example, since the sacrifice patterns SP1 and SP2 having higher etch rates than the anodes AE1 and AE2 are disposed between the pixel-defining film PDL and the anodes AE1 and AE2, the anodes AE1 and AE2 may be prevented from being etched together and thus damaged during the etching process.

After this, referring to FIG. 7G, the manufacturing method for the display panel, according to an embodiment of the disclosure, may include the step of forming the light-emitting element ED1 in the light-emitting opening OP1-E and the partition wall opening OP1-P. The step of forming the first light-emitting element ED1 may include forming a first light-emitting pattern EP1 and forming a first cathode CE1.

The step of forming the first light-emitting pattern EP1 may include a deposition process of a light-emitting layer. For example, the step of forming the first light-emitting pattern EP1 may include performing a thermal evaporation on the light-emitting layer. The light-emitting layer may be separated by the tip portion formed on the partition wall PW, and may be deposited inside the first and second partition wall openings OP1-P and OP2-P and on the partition wall PW. The light-emitting layer formed in the first partition wall opening OP1-P may form the first light-emitting pattern EP1, and the light-emitting layer formed inside the second partition wall opening OP2-P and on the partition wall PW may form a first dummy layer D1. For example, the first light-emitting pattern EP1 may be formed on the first anode AE1 to overlap the first partition wall opening OP1-P, and the first light-emitting pattern EP1 may be formed covering the first anode AE1 and the pixel-defining film PDL.

The first dummy layer D1, formed together in the step of forming the first light-emitting pattern EP1, may include an organic material. For example, the first dummy layer D1 and the first light-emitting pattern EP1 may include a same material. The first dummy layer D1 and the first light-emitting pattern EP1 may be formed through one process, and the first dummy layer D1 may be formed separately from the first light-emitting pattern EP1 due to the undercut shape of the partition wall PW.

The step of forming the first cathode CE1 may include a deposition process of a cathode layer. For example, the step of forming the first cathode CE1 may include performing sputtering on the cathode layer. The cathode layer may be separated by the tip portion formed on the partition wall PW, and may be deposited inside the first and second partition wall openings OP1-P and OP2-P and on the partition wall PW. The cathode layer, formed in the first partition wall opening OP1-P, may form the first cathode CE1, and the cathode layer, formed inside the second partition wall opening OP2-P and on the partition wall PW, may form a second dummy layer D2. For example, the first cathode CE1 may be formed on the first light-emitting pattern EP1 to overlap the first partition wall opening OP1-P, and the first cathode CE1 may be formed covering the first light-emitting pattern EP1. The first cathode CE1 may be formed by contacting an inner side surface of the partition wall PW to extend along the inner side surface of the partition wall PW.

The second dummy layer D2, formed together in the step of forming the first cathode CE1, may include a conductive material. For example, the second dummy layer D2 and the first cathode CE1 may include a same material. The second dummy layer D2 and the first cathode CE1 may be formed through a process, and the second dummy layer D2 may be formed separately from the first cathode CE1 due to the undercut shape of the partition wall PW.

The first anode AE1, the first light-emitting pattern EP1, and the first cathode CE1 may be stacked each other in sequence in a third direction DR3. The first anode AE1, the first light-emitting pattern EP1, and the first cathode CE1 may form the first light-emitting element ED1.

After this, referring to FIGS. 7H and 71, the manufacturing method for the display panel, according to an embodiment of the disclosure, may include forming a lower inorganic encapsulation pattern LIL1 that covers the light-emitting element ED1. The step of forming the lower inorganic encapsulation pattern LIL1 may include depositing a first lower inorganic encapsulation layer LIL1-I, and removing a portion of the first lower inorganic encapsulation layer LIL1-I not overlapping the first light-emitting element ED1. With reference to FIG. 7H, the step of depositing the first lower inorganic encapsulation layer LIL-1 is described, and with reference to FIG. 7I, the step of removing the portion of the first lower inorganic encapsulation layer LIL1-I not overlapping the first light-emitting element ED1 is described.

First of all, referring to FIG. 7H, the step of forming the first lower inorganic encapsulation pattern LIL1 may include the step of depositing the first lower inorganic encapsulation layer LIL1-I. In an embodiment, the first lower inorganic encapsulation layer LIL1-I may be formed through a chemical vapor deposition (CVD) process. The first lower inorganic encapsulation layer LIL1-I may be formed to cover the first cathode CE1 and the partition wall PW. A portion of the first lower inorganic encapsulation layer LIL1-I may fill the first partition wall opening OP1-P and the groove GV.

After this, the manufacturing method for the display panel, according to an embodiment of the disclosure, may include forming a third photoresist layer PR3. In the step of forming the third photoresist layer PR3, after a preliminary photoresist layer is formed, the preliminary photoresist layer may be patterned by using a photo mask to thereby form the third photoresist layer PR3. Through the patterning process, the third photoresist layer PR3 may be formed in patterns corresponding to the first light-emitting element ED1.

After this, referring to FIG. 7I, the step of forming the first lower inorganic encapsulation pattern LIL1 may include the step of removing a portion of the first lower inorganic encapsulation layer LIL1-I (see FIG. 7H) not overlapping the first light-emitting element ED1.

In the step of removing the portion of the first lower inorganic encapsulation layer LIL1-I not overlapping the first light-emitting element ED1, the first lower inorganic encapsulation layer LIL1-I may be dry etched by using the third photoresist layer PR3 as a mask. A portion of the first lower inorganic encapsulation layer LIL1-I not overlapping the third photoresist layer PR3 may be removed, and the first lower inorganic encapsulation pattern LIL1 may be formed in the remaining portion of the first lower inorganic encapsulation layer LIL1-I which is not etched. The first lower inorganic encapsulation pattern LIL1, formed by etching, may fill the first partition wall opening OP1-P, and may not overlap the groove GV.

After this, referring to FIG. 7J, the manufacturing method for the display panel, according to an embodiment of the disclosure, may include removing dummy layers D1 and D2. The second dummy layer D2, among the dummy layers D1 and D2, may be removed by wet etching, and the first dummy layer D1, among the dummy layers D1 and D2, may be removed by a stripper. During the process, the third photoresist layer PR3 (see FIG. 7I) may be removed.

After this, referring to FIG. 7K, the manufacturing method for the display panel according to an embodiment of the disclosure may include forming a second light-emitting element ED2 and a second lower inorganic encapsulation pattern LIL2. The process of forming the second light-emitting element ED2 and the second lower inorganic encapsulation pattern LIL2 may be substantially the same as the process of forming the first light-emitting element ED1 and the first lower inorganic encapsulation pattern LIL1 described with reference to FIGS. 7G to 7J.

Although omitted for the convenience of description, the manufacturing method for the display panel, according to an embodiment of the disclosure, may include forming a third light-emitting element ED3 (see FIG. 6) and a third lower inorganic encapsulation pattern LIL3 (see FIG. 6). The process of forming the third light-emitting element ED3 and the third lower inorganic encapsulation pattern LIL3 may be substantially the same as the process of forming the first light-emitting element ED1 and the first lower inorganic encapsulation pattern LIL1 described with reference to FIGS. 7G to 7J.

After this, referring to FIG. 7L, the manufacturing method for the display panel may include forming an organic encapsulation film OL on the first and second lower inorganic encapsulation patterns LIL1 and LIL2 and forming an upper inorganic encapsulation film UIL on the organic encapsulation film OL to thereby complete the display panel DP.

The organic encapsulation film OL may be formed by applying an organic material through inkjet, for example, but an embodiment of the disclosure is not limited thereto. The organic encapsulation film OL may provide a planarized upper surface. The organic encapsulation film OL may fill the groove GV of the partition wall PW.

After this, the upper inorganic encapsulation film UIL may be formed by depositing an inorganic material. Through this, the display panel DP, including the base layer BL, the circuit element layer DP-CL, the display element layer DP-OLED, and the thin-film encapsulation layer TFE, may be formed.

FIG. 8 is a schematic cross-sectional view taken along line I-I′ of FIG. 3. The cross-sectional view in FIG. 8, corresponding to the cross-sectional view in FIG. 5, illustrates another embodiment of the disclosure. In describing with reference to FIG. 8, same/similar components as/with the components described with reference to FIGS. 1 to 7L are denoted as the same/similar reference numerals or symbols, and duplicate descriptions are omitted.

Referring to FIG. 8, a display panel DPa may include a base layer BL, a circuit element layer DP-CL, a display element layer DP-OLEDa, and/or a thin-film encapsulation layer TFE. The display element layer DP-OLEDa may include a light-emitting element ED, a sacrifice pattern SP, a pixel-defining film PDL, and a partition wall PWa.

The partition wall PWa may be disposed on the pixel-defining film PDL. The partition wall PWa may include multiple layers stacked each other in sequence. For example, the partition wall PWa may include a first partition wall layer L1 and a second partition wall layer L2. The first partition wall layer L1 may be disposed on the pixel-defining film PDL, and the second partition wall layer L2 may be disposed on the first partition wall layer L1. It is illustrated that the partition wall PWa includes the first and second partition wall layers L1 and L2 as an example, and an embodiment of the disclosure is not limited thereto. For example, the partition wall PWa may include at least three partition wall layers.

As illustrated in FIG. 8, the thickness of the first partition wall layer L1 may be substantially the same as the thickness of the second partition wall layer L2, but an embodiment of the disclosure is not limited thereto. For example, the thickness of the second partition wall layer L2 may be larger than the thickness of the first partition wall layer L1.

The partition wall PWa may include a conductive material. In an embodiment, the first partition wall layer L1 of the partition wall PWa may include at least one of molybdenum (Mo), tungsten (W), and a molybdenum-tungsten (Mo—W) alloy, and the second partition wall layer L2 of the partition wall PWa may include at least one of titanium (Ti) and aluminum (Al).

The partition wall PWa may have an undercut shape on a cross-section. The partition wall PWa may include first portions P1a, second portions P2a, and third portions P3a. The first portions P1a, the second portions P2a, and the third portions P3a of the partition wall PWa may be substantially the same as the first portions P1, the second portions P2, and the third portions P3 in FIG. 5. The partition wall PWa may include tip portions. For example, the third portions P3a of the partition wall PWa may protrude toward a light-emitting opening OP-E to form the tip portions. For example, the third portions P3a protruding from the second portions P2a may be defined as the tip portions (or include the tip portions). For example, inner side surfaces of the third portions P3a may be closer to the center of an anode AE than inner side surfaces of the second portions P2a.

The partition wall PWa may have a partition wall opening OP-P and a groove GV (defined therein). A length DD1a of the partition wall PWa from lower surfaces B_P1 of the first portions P1a, adjacent to the second portions P2a, to lower surfaces B_P3 of the third portions P3a may be about 0.6 μm. A thickness (sum of T1a and T2) of the partition wall PW may be in a range of about 0.2 μm to about 0.5 μm. In an embodiment, the thickness T1a of the first partition wall layer L1 may be about 0.2 μm, and the thickness T2 of the second partition wall layer L2 may be about 0.25 μm.

FIG. 9 is a schematic cross-sectional view taken along line I-I′ of FIG. 3. The cross-sectional view in FIG. 9, corresponding to the cross-sectional view in FIG. 5, illustrates another embodiment of the disclosure. In describing with reference to FIG. 9, same/similar components as/with the components described with reference to FIGS. 1 to 8 are denoted as the same/similar reference numerals or symbols, and duplicate descriptions are omitted.

Referring to FIG. 9, a display panel DPb may include a base layer BL, a circuit element layer DP-CL, a display element layer DP-OLEDb, and a thin-film encapsulation layer TFE. The display element layer DP-OLEDb may include a light-emitting element ED, a sacrifice pattern SP, a pixel-defining film PDL, and a partition wall PWb.

The partition wall PWb may be disposed on the pixel-defining film PDL. The partition wall PWb may include multiple layers stacked each other in sequence. For example, the partition wall PWb may include a first partition wall layer L1a and a second partition wall layer L2a. The first partition wall layer L1a may be disposed on a pixel-defining film PDL, and the second partition wall layer L2a may be disposed on the first partition wall layer L1a. The partition wall PWb in FIG. 9 may be substantially the same as the partition wall PWa in FIG. 8. However, a length DD1b of the partition wall PWb from the lower surfaces B_P1 (see FIG. 5) of the first portions P1a (see FIG. 8), adjacent to the second portions P2a (see FIG. 8), to the lower surfaces B_P3 (see FIG. 5) of the third portions P3a (see FIG. 8) may be about 1 μm.

Referring to FIGS. 8 and 9, molybdenum (Mo), tungsten (W), or a molybdenum-tungsten (Mo—W) alloy may have high adhesiveness and low contact resistance characteristics. However, molybdenum (Mo), tungsten (W), or a molybdenum-tungsten (Mo—W) alloy may have high stress characteristics, so that the same is required to be manufactured to have a small thickness. However, according to an embodiment of the disclosure, since the partition wall PWa or PWb has a shape having the groove GV defined therein, the partition wall PWa or PWb may have a large height DD1a or DD1b even in case of including molybdenum (Mo), tungsten (W), or a molybdenum-tungsten (Mo—W) alloy. For example, the display panel DPa or DPb according to an embodiment of the disclosure may include the partition wall PWa or PWb which has a high adhesiveness for the cathode CE and the lower inorganic encapsulation pattern LIL, has a low contact resistance for the cathode CE, and has a large height DD1a or DD1b.

Since the partition wall PWa or PWb may include a second partition wall layer L2 or L2a having a low stress, the thickness of the first partition wall layer L1 or L1a, containing molybdenum (Mo), tungsten (W), or a molybdenum-tungsten (Mo—W) alloy, may be miniaturized. As a result, the stress of the partition wall PWa or PWb may be reduced and thus, the partition wall PWa or PWb may have a larger height DD1a or DD1b.

According to what is previously described, since a partition wall has a shape having a groove defined therein, the partition wall may have a large height even in case of including molybdenum (Mo), tungsten (W), or a molybdenum-tungsten (Mo—W) alloy. The partition wall of the display panel may have a large height, a high adhesion to a cathode and a lower inorganic encapsulation pattern, and a low contact resistance with the cathode. As a result, pixel defects (dark spots, pixel shrinkage, etc.) of the display panel may be reduced or eliminated.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel comprising:
a base layer;
a pixel-defining film disposed on the base layer and having a light-emitting opening;
a partition wall disposed on the pixel-defining film, and having a partition wall opening overlapping the light-emitting opening and a groove overlapping the pixel-defining film; and
a light-emitting element including an anode, a light-emitting pattern, and a cathode in contact with the partition wall, and disposed in the light-emitting opening and the partition wall opening.

2. The display panel of claim 1, wherein the groove is concave from an upper surface of the partition wall in a thick direction of the base layer.

3. The display panel of claim 1, wherein the partition wall comprises:
first portions disposed on the pixel-defining film;
second portions extending from the first portions in a thickness direction of the base layer; and
third portions extending from the second portions toward a center of the partition wall opening.

4. The display panel of claim 3, wherein the third portions protruding from the second portions comprise tip portions.

5. The display panel of claim 3, wherein
the partition wall opening comprises a first region defined by the third portions of the partition wall and a second region defined by the second portions of the partition wall, and
a width of the first region in a direction is smaller than a width of the second region in the direction.

6. The display panel of claim 3, wherein a length of the partition wall from lower surfaces of the first portions, adjacent to the second portions, to lower surfaces of the third portions is in a range of about 0.5 μm to about 1 μm.

7. The display panel of claim 1, further comprising:
a lower inorganic encapsulation pattern which covers the light-emitting element,
wherein the lower inorganic encapsulation pattern fills the partition wall opening.

8. The display panel of claim 7, further comprising:
an organic encapsulation film disposed on the lower inorganic encapsulation pattern,
wherein the organic encapsulation film fills the groove.

9. The display panel of claim 1, wherein the partition wall comprises at least one of molybdenum (Mo), tungsten (W), and a molybdenum-tungsten (Mo—W) alloy.

10. The display panel of claim 1, wherein the partition wall comprises:
a first partition wall layer disposed on the pixel-defining film; and
a second partition wall layer disposed on the first partition wall layer.

11. The display panel of claim 10, wherein the first partition wall layer comprises at least one of molybdenum (Mo), tungsten (W), and a molybdenum-tungsten (Mo—W) alloy.

12. The display panel of claim 10, wherein the second partition wall layer comprises at least one of titanium (Ti) and aluminum (Al).

13. The display panel of claim 1, wherein the partition wall has a thickness in a range of about 0.2 μm to about 0.5 μm.

14. A manufacturing method for a display panel, comprising:
providing a preliminary display panel including a base layer, an anode disposed on the base layer, and a pixel-defining film covering the anode;
forming, on the preliminary display panel, an auxiliary layer overlapping the anode;
forming a preliminary partition wall on the pixel-defining film and the auxiliary layer;
etching the preliminary partition wall and the auxiliary layer to form a partition wall comprising partition wall opening;
etching the pixel-defining film to form a light-emitting opening overlapping the partition wall opening; and
forming a light-emitting element in the light-emitting opening and the partition wall opening.

15. The manufacturing method of claim 14, wherein the etching of the preliminary partition wall and the auxiliary layer to form the partition wall comprising the partition wall opening comprises:
etching the preliminary partition wall to form a first region of the partition wall opening; and
etching the auxiliary layer to form a second region of the partition wall opening.

16. The manufacturing method of claim 14, wherein
the partition wall comprises a groove overlapping the pixel-defining film, and
the groove is concave from an upper surface of the partition wall in a thickness direction of the base layer.

17. The manufacturing method of claim 16, further comprising:
forming a lower inorganic encapsulation pattern which covers the light-emitting element,
wherein the lower inorganic encapsulation pattern fills the partition wall opening.

18. The manufacturing method of claim 17, further comprising:
forming an organic encapsulation film on the lower inorganic encapsulation pattern,
wherein the organic encapsulation film fills the groove.

19. The manufacturing method of claim 14, wherein the forming of the preliminary partition wall on the pixel-defining film and the auxiliary layer comprises depositing at least one of molybdenum (Mo), tungsten (W), and a molybdenum-tungsten (Mo—W) alloy.

20. The manufacturing method of claim 14, wherein the forming of the preliminary partition wall on the pixel-defining film and the auxiliary layer comprises:
depositing a first preliminary partition wall layer on the pixel-defining film and the auxiliary layer; and
depositing a second preliminary partition wall layer on the first preliminary partition wall layer.
